(19) United States
(12) Patent Application Publication
(10) Pub. No.: US 2025/0011646 A1
(43) Pub. Date: Jan. 9, 2025

(54) Light-Emitting Device, Light-Emitting Substrate and Light-Emitting Apparatus

(71) Applicant: BOE TECHNOLOGY GROUP CO., LTD., Chaoyang District, Beijing (CN)

(72) Inventors: Wenzhu Jing, Beijing (CN); Dongxu Zhang, Beijing (CN); Xueqin Chen, Beijing (CN); Bingyan Liang, Beijing (CN); Lei Chen, Beijing (CN)

(21) Appl. No.: 18/580,198

(22) PCT Filed: Jan. 28, 2023
(86) PCT No.: PCT/CN2023/073586

§ 371 Date: Jan. 18, 2024

(51) Int. Cl. C09K 11/06; C09K 11/02; H10K 50/12; H10K 50/858; H10K 85/60

(52) U.S. Cl. CPC C09K 11/06; C09K 11/02; H10K 85/626; H10K 85/631; C09K 2211/1007; C09K 2211/1011; C09K 2211/1014; C09K 2211/1022; H10K 50/12; H10K 50/858

(57) ABSTRACT

A light-emitting device includes at least two capping layers which include a first capping layer closest to a second electrode. A refractive index of a capping layer closer to the second electrode is greater than that of a capping layer farther away from the second electrode. A first capping layer material satisfies at least one of: the intermolecular minimum center-of-mass distance of the first capping layer material is in a range of 2 Å to 6 Å, and the dimension of the molecular structure of the first capping layer material in the third direction is in a range of 3 Å to 15 Å; and further satisfies at least one of: the molecular volume of the first capping layer material is in a range of 4000 Bohr³ to 8000 Bohr³, and the molecular density of the first capping layer material is in a range of 1.2 g/cm³ to 2.6 g/cm³.

### CROSS-REFERENCE TO RELATED APPLICATION

This application is the United States national phase of International Patent Application No. PCT/CN2023/073586, filed Jan. 28, 2023, the disclosure of which is hereby incorporated by reference in its entirety.

### BACKGROUND OF THE INVENTION

### Field of the Invention

The present disclosure relates to the field of light-emission and display technologies, and in particular, to a light-emitting device, a light-emitting substrate and a light-emitting apparatus.

### Description of Related Art

Organic light-emitting diodes (OLEDs) have been increasingly widely used in recent years due to their characteristics of self-luminescence, wide viewing angle, short response time, high luminous efficiency, low operating voltage, thin substrate thickness, being capable of producing large-size and bendable substrate and simple manufacturing process.

### SUMMARY OF THE INVENTION

In an aspect, a light-emitting device is provided. The light-emitting device includes a first electrode, a second electrode, and a light-emitting layer disposed between the first electrode and the second electrode. The light-emitting device further includes at least two capping layers stacked on a side of the second electrode away from the first electrode. A material of each capping layer in the at least two capping layers includes an organic material. A refractive index of a capping layer relatively closer to the second electrode is greater than a refractive index of a capping layer relatively farther away from the second electrode.

The at least two capping layers include a first capping layer, and the first capping layer is closest to the second electrode. The first capping layer includes a first capping layer material, and an intermolecular minimum center-of-mass distance of the first capping layer material and a dimension of a molecular structure of the first capping layer material in a third direction satisfy at least one of following conditions: the intermolecular minimum center-of-mass distance of the first capping layer material is in a range of 2 Å to 6 Å, inclusive, and the dimension of the molecular structure of the first capping layer material in the third direction is in a range of 3 Å to 15 Å, inclusive.

A molecular volume and a molecular density of the first capping layer material satisfy at least one of following conditions: the molecular volume of the first capping layer material is in a range of 4000 Bohr³ to 8000 Bohr³, inclusive, and the molecular density of the first capping layer material is in a range of 1.2 g/cm³ to 2.6 g/cm³, inclusive.

The molecular structure has a dimension in a first direction, a dimension in a second direction and the dimension in the third direction; and the first direction, the second direction and the third direction are perpendicular to each other. The dimension in the first direction is greater than or equal to the dimension in the second direction, and the dimension in the second direction is greater than or equal to the dimension in the third direction.

In some embodiments, a difference in refractive index between two adjacent capping layers is in a range of 0.2 to 0.8, inclusive.

In some embodiments, the at least two capping layers further include a second capping layer, and the second capping layer is disposed on a side of the first capping layer away from the second electrode. The second capping layer includes a second capping layer material, and an intermolecular minimum center-of-mass distance of the second capping layer material and a dimension of a molecular structure of the second capping layer material in the third direction satisfy at least one of following conditions: the intermolecular minimum center-of-mass distance of the second capping layer material is in a range of 2.5 Å to 10 Å, inclusive, and the dimension of the molecular structure of the second capping layer material in the third direction is in a range of 6 Å to 25 Å, inclusive. A molecular volume and a molecular density of the second capping layer material satisfy at least one of following conditions: the molecular volume of the second capping layer material is in a range of 6000 Bohr³ to 20000 Bohr³, inclusive, and the molecular density of the second capping layer material is in a range of 0.8 g/cm³ to 1.48 g/cm³, inclusive.

In some embodiments, the at least two capping layers further include a second capping layer. Within a light-emitting wavelength range of 300 nm to 800 nm, a refractive index of the first capping layer is in a range of 1.85 to 3.0, inclusive, and a refractive index of the second capping layer is in a range of 1.0 to 1.75, inclusive.

In some embodiments, the first capping layer material is selected from any one of structures represented by a following general formula I:

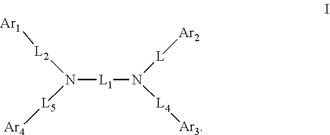

Where L₁ is selected from any one of substituted or unsubstituted arylene, substituted or unsubstituted fused ring arylene, substituted or unsubstituted heteroarylene, and substituted or unsubstituted fused ring heteroarylene. L₂, L₃, L₄ and L₅ are the same or different, and are each independently selected from any one of substituted or unsubstituted C2 to C30 alkylene, substituted or unsubstituted C6 to C60 arylene, and substituted or unsubstituted C5 to C60 heteroarylene. Ar₁, Ar₂, Ar₃ and Ar₄ are the same or different, and are each independently selected from any one of substituted or unsubstituted C2 to C30 alkyl, substituted or unsubstituted C6 to C60 aryl, and substituted or unsubstituted C5 to C60 heteroaryl.

In some embodiments, L₁ is selected from any one of structural formulas

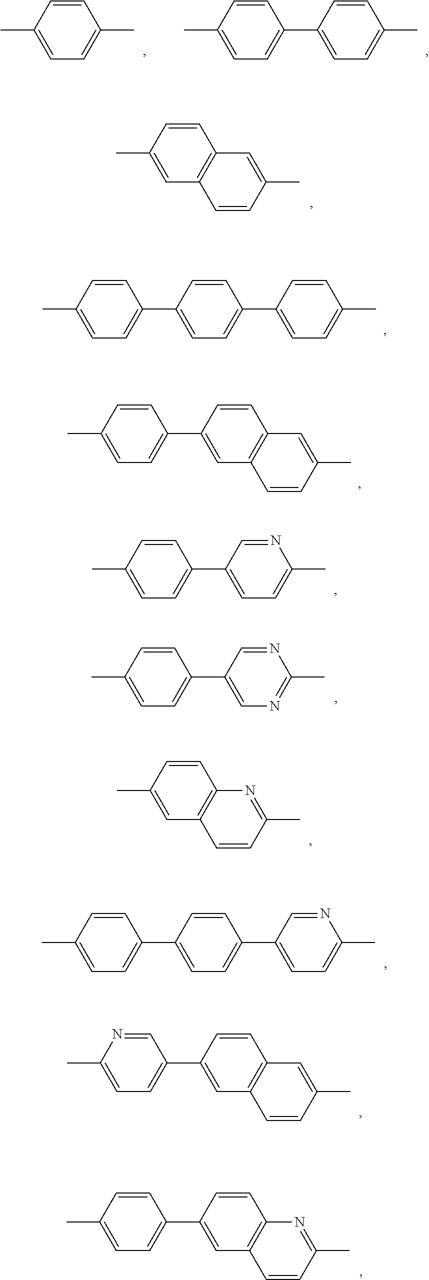

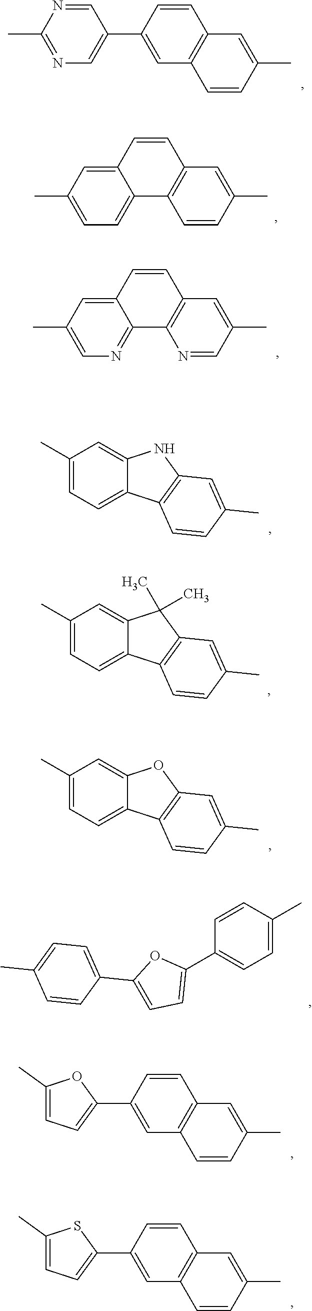

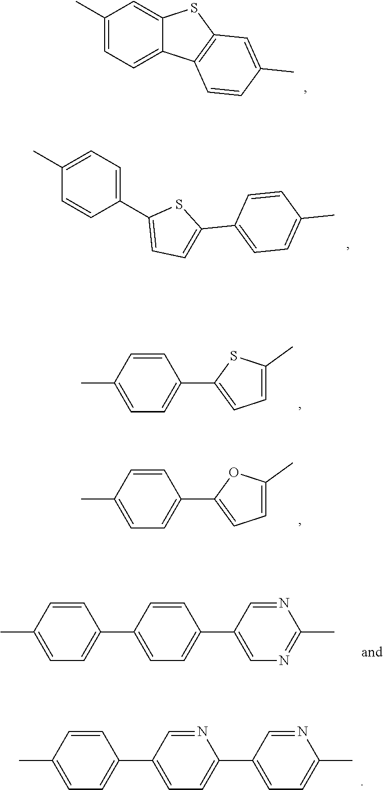

In some embodiments, Ar₁, Ar₂, Ar₃ and Ar₄ are each independently selected from any one of substituted or unsubstituted phenyl, substituted or unsubstituted naphthyl, substituted or unsubstituted anthryl, substituted or unsubstituted pyrimidinyl and substituted or unsubstituted dibenzo five-membered heterocycle.

In some embodiments, Ar₁, Ar₂, Ar₃ and Ar₄ are each independently selected from any one of structural formulas

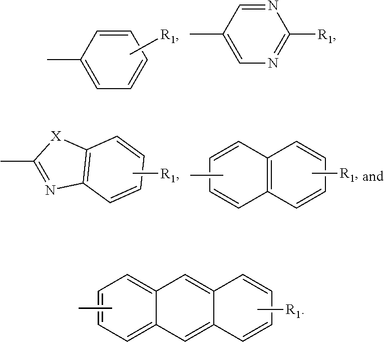

Where R₁ is selected from any one of hydrogen, substituted or unsubstituted C2 to C30 alkyl, substituted or unsubstituted C6 to C60 aryl, and substituted or unsubstituted C5 to C60 heteroaryl. X is selected from any one of carbon, nitrogen, oxygen and sulfur.

In some embodiments, the second capping layer material is selected from any one of structures represented by a following general formula II:

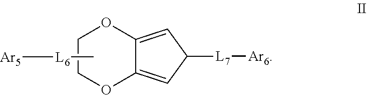

Wherein Ar₅ and Ar₆ are the same or different, and are each independently selected from any one of

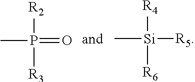

R₂, R₃, R₄, R₅ and R₆ are the same or different, and are each independently selected from any one of substituted or unsubstituted C2 to C30 alkyl, substituted or unsubstituted C6 to C60 aryl, and substituted or unsubstituted C5 to C60 heteroaryl.

L₆ and L₇ are the same or different, and are each independently selected from any one of a single bond, substituted or unsubstituted C2 to C30 alkylene, substituted or unsubstituted C6 to C60 arylene, and substituted or unsubstituted C5 to C60 heteroarylene.

In some embodiments, a thickness of the first capping layer is in a range of 50 nm to 90 nm, inclusive; and a thickness of the second capping layer is in a range of 50 nm to 90 nm, inclusive.

In some embodiments, the light-emitting device is a top-emission device, and the at least two capping layers are disposed on a light-exiting side of the light-emitting device.

In some embodiments, the first electrode is an anode, and the second electrode is a cathode.

In some embodiments, the light-emitting layer includes a first sub-pixel light-emitting layer, a second sub-pixel light-emitting layer and a third sub-pixel light-emitting layer. The first sub-pixel light-emitting layer is configured to emit one of red light, blue light and green light, the second sub-pixel light-emitting layer is configured to emit another of the red light, the blue light and the green light, and the third sub-pixel light-emitting layer is configured to emit a last one of the red light, the blue light and the green light.

In some embodiments, a material of the light-emitting layer includes any one of a fluorescent luminescent material, a phosphorescent luminescent material and a thermally activated delayed fluorescent material.

In some embodiments, any one of the first sub-pixel light-emitting layer, the second sub-pixel light-emitting layer and the third sub-pixel light-emitting layer is configured to emit the blue light. A material of a sub-pixel light-emitting layer that emits the blue light includes a host material and a guest material.

A structural formula of the host material is as follows:

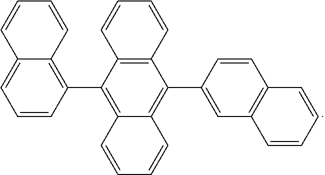 [SMILES: c1ccc2cc(-c3c4ccccc4c(-c4cccc5ccccc45)c4ccccc34)ccc2c1]

A structural formula of the guest material is as follows:

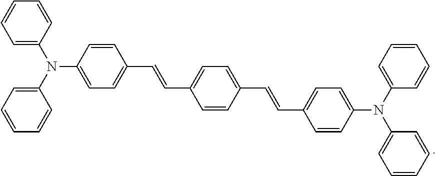 [SMILES: C(=C\c1ccc(N(c2ccccc2)c2ccccc2)cc1)/c1ccc(/C=C/c2ccc(N(c3ccccc3)c3ccccc3)cc2)cc1]

In addition, the light-emitting device further include at least one of a hole injection layer, a hole transport layer and an electron blocking layer that is disposed between the first electrode and the light-emitting layer. The light-emitting device further include at least one of a hole blocking layer, an electron transport layer and an electron injection layer that is disposed between the light-emitting layer and the second electrode.

In another aspect, a light-emitting substrate is provided. The light-emitting substrate includes the light-emitting device as described in any of the above embodiments.

In yet another aspect, a light-emitting apparatus is provided. The light-emitting apparatus includes the light-emitting substrate as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a light-emitting device, in accordance with some embodiments of the present disclosure;

FIG. 2 is a structural diagram after molecular deposition, in accordance with some embodiments of the present disclosure;

FIG. 3 is a diagram of a molecular structure, in accordance with some embodiments of the present disclosure;

FIG. 4 is a structural diagram of another light-emitting device, in accordance with some embodiments of the present disclosure;

FIG. 5A is a structural diagram of yet another light-emitting device, in accordance with some embodiments of the present disclosure;

FIG. 5B is an electroluminescence spectrum map of the luminescent material, in accordance with some embodiments of the present disclosure;

FIG. 6 is a structural diagram of yet another light-emitting device, in accordance with some embodiments of the present disclosure;

FIG. 7 is a structural diagram of a light-emitting substrate, in accordance with some embodiments of the present disclosure; and

FIG. 8 is a structural diagram of a light-emitting apparatus, in accordance with some embodiments of the present disclosure.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; and it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Organic light-emitting diode (OLED) displays have become a new generation of flat panel displays due to their advantages of self-luminescence, low power consumption, high resolution, large color gamut, no need for backlights, and flexibility and being bendable. In particular, flexible OLED displays are highly favored since they are foldable and bendable.

OLED devices may be classified into bottom-emission devices and top-emission devices according to an exiting direction of light generated by a light-emitting layer. The bottom-emission device has a transparent anode formed below the light-emitting layer. For an active-matrix OLED device, a portion of a driving circuit provided with thin film transistors (TFTs) is opaque, resulting in a decrease in a light-emitting area of the OLED device.

The top-emission device includes a reflective anode, an organic functional layer and a transparent cathode. The light extraction efficiency is enhanced through microcavity effect between the anode and the cathode. The microcavity effect mainly refers to optical interference inside the OLED device, which uses redistribution of densities of photons of different energy states to only allow light with a specific wavelength to exit at a specific angle after conforming to the resonant cavity mode.

In order to improve the luminous efficiency of the top-emission device, a capping layer (CPL) is provided on the cathode. The existing capping layer is generally a combination of an organic layer with high refractive index and an inorganic layer with low refractive index, thereby improving the light extraction efficiency of the OLED device. However, the introduction of the inorganic layer with low refractive index makes the OLED device less flexible and prone to breakage.

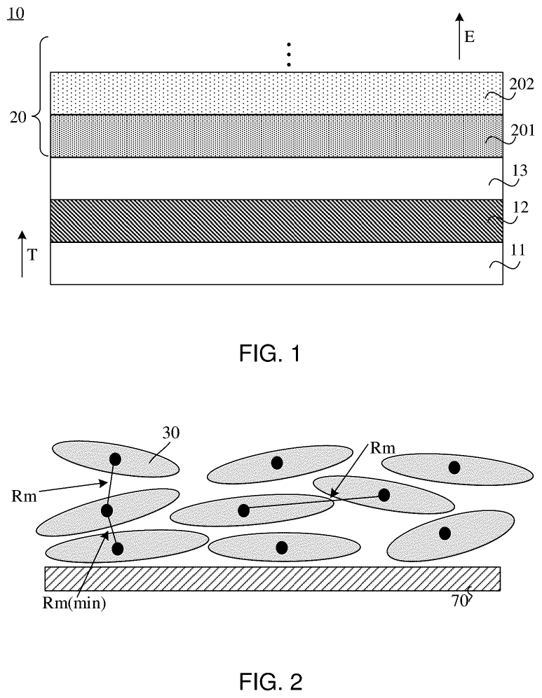

In light of this, as shown in FIG. 1, embodiments of the present disclosure provide a light-emitting device 10. The light-emitting device 10 includes a first electrode 11 and a second electrode 13, and a light-emitting layer 12 disposed between the first electrode 11 and the second electrode 13.

For example, the first electrode 11 is one of the anode and the cathode, and the second electrode 13 is the other of the anode and the cathode.

The light-emitting device 10 further include at least two capping layers 20, which are stacked on a side of the second electrode 13 away from the first electrode 11. The material of each capping layer 20 in the at least two capping layers 20 includes an organic material. Moreover, a refractive index n of a capping layer 20 relatively closer to the second electrode 13 is greater than a refractive index n of a capping layer 20 relatively farther away from the second electrode 13.

For example, as shown in FIG. 1, a direction perpendicular to a surface of the light-emitting layer 12 away from the second electrode 13 and directed from the light-emitting layer 12 to the second electrode 13 is a light extraction direction E of the light-emitting device 10. A plurality of capping layers 20 are provided on the side of the second electrode 13 away from the first electrode 11, and the plurality of capping layers 20 are stacked in sequence. The material of each capping layer 20 is provided to be an organic material. Since the organic material has good flexibility, the plurality of capping layers 20 use organic materials, so that the flexibility of the light-emitting device 10 may be improved and the light-emitting device 10 is less prone to breakage.

For example, as shown in FIG. 1, the plurality of capping layers 20 are, from a capping layer 20 relatively closer to the second electrode 13 to a capping layer 20 relatively farther away from the second electrode 13, sequentially labeled as a first capping layer 201, a second capping layer 202, . . . , and an mth capping layer, where m is a positive integer greater than or equal to 3. The first capping layer 201, the second capping layer 202, . . . , and the mth capping layer are sequentially away from the second electrode 13. Therefore, from a refractive index n1 of the first capping layer 201, a refractive index n2 of the second capping layer 202, . . . , until a refractive index nm of the mth capping layer, for any two adjacent capping layers, a refractive index of the former is greater than a refractive index of the latter.

By setting the refractive index n of the capping layer 20 relatively closer to the second electrode 13 to be greater than the refractive index n of the capping layer 20 relatively farther from the second electrode 13, an optical waveguide effect may be reduced, thereby improving the light extraction efficiency of the light-emitting device 10. The optical waveguide effect refers to an effect that a phenomenon of total reflection of light at an interface of media with different refractive indexes causes the light to propagate within a waveguide and its surrounding limited area.

The at least two capping layers 20 include a first capping layer 201, and the first capping layer 201 is closest to the second electrode 13. The first capping layer 201 includes a first capping layer material, and an intermolecular minimum center-of-mass distance Rm1(min) of the first capping layer material and a dimension c1 of a molecular structure of the first capping layer material in a third direction Z satisfy at least one of the following conditions: the intermolecular minimum center-of-mass distance Rm1(min) of the first capping layer material is in a range of 2 Å to 6 Å, inclusive (i.e., 2 Å≤Rm1(min)≤6 Å), and the dimension c1 of the molecular structure of the first capping layer material in the third direction Z is in a range of 3 Å to 15 Å, inclusive (i.e., 3 Å≤c1≤15 Å).

It will be noted that, as shown in FIG. 2, the molecules 30 are deposited on a substrate 70. The arrangement of the molecules 30 is shown in FIG. 2. The intermolecular minimum center-of-mass distance Rm(min) refers to a minimum value of the center-of-mass distances Rm each between two molecules 30 (which is the intermolecular minimum center-of-mass distance Rm(min)) obtained by measuring a center-of-mass distance Rm between every two molecules 30 among all combinations of molecules 30 in pairs. The center-of-mass of the molecular is an abbreviation for the mass center of the molecular, which refers to an imaginary point, in a material system, at which the mass is considered to be concentrated.

For example, the intermolecular minimum center-of-mass distance Rm1 (min) of the first capping layer material is 2 Å, 3 Å, 4 Å, 5 Å or 6 Å, which is not limited here.

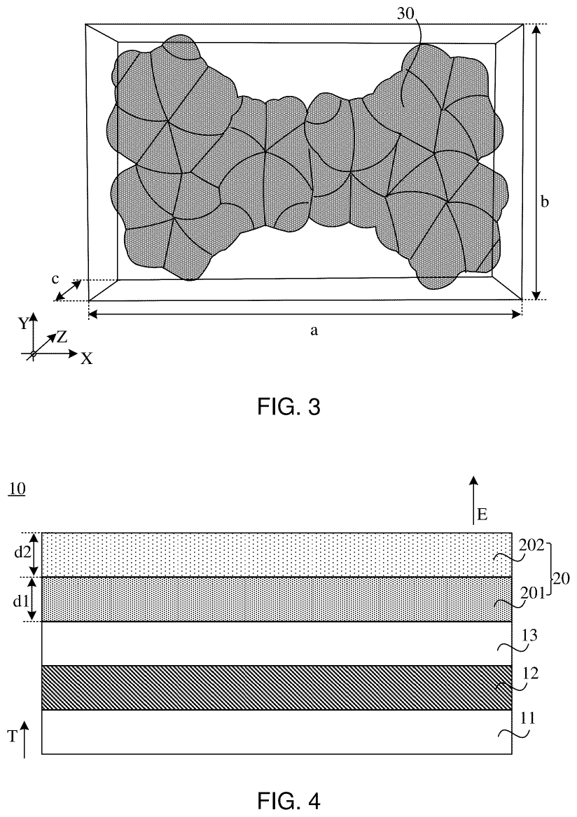

It will be noted that, as shown in FIG. 3, the molecular structure has a dimension a in a first direction X, a dimension b in a second direction Y, and a dimension c in a third direction Z. The first direction X, the second direction Y, and the third direction Z are perpendicular to each other. Moreover, the dimension a in the first direction X is greater than or equal to the dimension b in the second direction Y, and the dimension b in the second direction Y is greater than or equal to the dimension c in the third direction Z (i.e., a b c). For example, the dimension a of the molecular structure in the first direction X represents a length of the molecular structure, the dimension b of the molecular structure in the second direction Y represents a width of the molecular structure, and the dimension c of the molecular structure in the third direction Z represents a height of the molecular structure. The first direction X, the second direction Y and the third direction Z are perpendicular to each other. For example, the first direction X and the second direction Y are in the same plane and perpendicular to each other, and the third direction Z is perpendicular to the plane where the first direction X and the second direction Y are located.

For example, the dimension c1 of the molecular structure of the first capping layer material in the third direction Z is 3 Å, 5 Å, 7 Å, 9 Å, 10 Å, 12 Å, 13 Å or 15 Å, which is not limited here.

It will be noted that the refractive index n of the material is negatively correlated with the intermolecular minimum center-of-mass distance Rm(min). For example, the smaller the intermolecular minimum center-of-mass distance Rm(min), the greater the refractive index n of the material. The refractive index n of the material is negatively correlated with the dimension c of the molecular structure in the third direction Z. For example, the smaller the dimension c of the molecular structure in the third direction Z, the greater the refractive index n of the material.

Moreover, the intermolecular minimum center-of-mass distance Rm(min) is positively correlated with the dimension c of the molecular structure in the third direction Z. For example, the smaller the dimension c of the molecular structure in the third direction Z, the smaller the intermolecular minimum center-of-mass distance Rm(min). Therefore, it is sufficient that the intermolecular minimum center-of-mass distance Rm1(min) of the first capping layer material and the dimension c1 of the molecular structure of the first capping layer material in the third direction Z satisfy at least one of the above conditions.

A molecular volume Vm1 and a molecular density ρm1 of the first capping layer material satisfy at least one of the following conditions: the molecular volume Vm1 of the first capping layer material is in a range of 4000 Bohr³ to 8000 Bohr³, inclusive (i.e., 4000 Bohr³≤Vm1 8000 Bohr³), and the molecular density ρm1 of the first capping layer material is in a range of 1.2 g/cm³ to 2.6 g/cm³, inclusive (i.e. 1.2 g/cm³≤ρm1≤2.6 g/cm³).

For example, the molecular volume Vm1 of the first capping layer material is 4000 Bohr³, 5000 Bohr³, 6000 Bohr³, 7000 Bohr³ or 8000 Bohr³, which is not limited here.

For example, the molecular density ρm1 of the first capping layer material is 1.2 g/cm³, 1.5 g/cm³, 1.8 g/cm³, 2.0 g/cm³, 2.2 g/cm³, 2.4 g/cm³ or 2.6 g/cm³, which is not limited here.

It will be noted that the refractive index n of the material is negatively correlated with the molecular volume Vm. For example, the smaller the molecular volume Vm, the greater the refractive index n of the material. The refractive index n of the material is positively correlated with the molecular density ρm. For example, the greater the molecular density ρm, the greater the refractive index n of the material.

Moreover, the molecular volume Vm is negatively correlated with the molecular density ρm. For example, the smaller the molecular volume Vm, the greater the molecular density ρm. Therefore, it is sufficient that the molecular volume Vm1 and the molecular density ρm1 of the first capping layer material satisfy at least one of the above conditions.

Relationship of the intermolecular minimum center-of-mass distance Rm(min), the dimension c of the molecular structure in the third direction Z, the molecular volume Vm, the molecular density ρm and the refractive index n may further be understood according to the Lorentz-Lorenz relationship.

The Lorentz-Lorenz relationship is as following:

$$\frac{{n}^{2} - 1}{{n}^{2} + 2} = \frac{4 π}{3} N α .$$

Where n is the refractive index, N is the number of molecules per unit volume, and α is average polarizability. The four parameters of the intermolecular minimum center-of-mass distance Rm(min), the dimension c of the molecular structure in the third direction Z, the molecular volume Vm, the molecular density ρm are each directly or indirectly affect the number N of molecules per unit volume and the average polarizability α.

Molecular polarizability is a microscopic parameter that describes polarization characteristics of a dielectric, and abbreviated as polarizability. The average polarizability α of molecules is an average value of polarizability of molecules.

The intermolecular minimum center-of-mass distance Rm(min), the dimension c of the molecular structure in the third direction Z and the molecular volume Vm are each negatively correlated with the number N of molecules per unit volume. For example, the smaller the intermolecular minimum center-of-mass distance Rm(min), the greater the number N of molecules per unit volume; the smaller the dimension c of the molecular structure in the third direction Z, the greater the number N of molecules per unit volume; and the smaller the molecular volume Vm, the greater the number N of molecules per unit volume. The molecular density ρm is positively correlated with the number N of molecules per unit volume. For example, the greater the molecular density ρm, the greater the number N of molecules per unit volume.

The number N of molecules per unit volume is positively correlated with the refractive index n. For example, the greater the number N of molecules per unit volume, the greater the refractive index n.

The dimension c of the molecular structure in the third direction Z is negatively correlated with the average polarizability α. For example, the smaller the dimension c of the molecular structure in the third direction Z, the greater the average polarizability α.

The average polarizability α is positively correlated with the refractive index n. For example, the greater the average polarizability α, the greater the refractive index n.

Therefore, in order to make the refractive index n1 of the first capping layer 201 made of the first capping layer material provided in the embodiments of the present disclosure largest in the plurality of capping layers 20, the intermolecular minimum center-of-mass distance Rm1(min) of the first capping layer material and the dimension c1 of the molecular structure of the first capping layer material in the third direction Z satisfy at least one of the above conditions, that is, the intermolecular minimum center-of-mass distance Rm1(min) of the first capping layer material is in the range of 2 Å to 6 Å, inclusive (i.e., 2 Å≤Rm1(min)≤6 Å), and the dimension c1 of the molecular structure of the first capping layer material in the third direction Z is in the range of 3 Å to 15 Å, inclusive (i.e., 3 Å≤c1≤15 Å); moreover, the molecular volume Vm1 and the molecular density ρm1 of the first capping layer material satisfy at least one of the above conditions, that is, the molecular volume Vm1 of the first capping layer material is in the range of 4000 Bohr³ to 8000 Bohr³, inclusive (i.e., 4000 Bohr³≤Vm1 8000 Bohr³), and the molecular density ρm1 of the first capping layer material is in the range of 1.2 g/cm³ to 2.6 g/cm³, inclusive (i.e. 1.2 g/cm³≤ρm1≤2.6 g/cm³). Therefore, the provision of the capping layer 20 may meet the requirement of improving the light extraction efficiency of the light-emitting device 10.

Therefore, the embodiments of the present disclosure provide the plurality of capping layers 20 that are all made of organic materials, and the refractive index n of the capping layer 20 relatively closer to the second electrode 13 is greater than the refractive index n of the capping layer 20 relatively farther away from the second electrode 13. Such provision may not only improve the flexibility of the light-emitting device 10, but also improve the light extraction efficiency of the light-emitting device 10. The parameters of the first capping layer material (i.e., the material of the capping layer closest to the second electrode 13 in the plurality of capping layers 20) are further set to effectively ensure that the refractive index n of the first capping layer 201 (i.e., the capping layer closest to the second electrode 13 in the plurality of capping layers 20) meets the requirement of improving the light extraction efficiency of the light-emitting device 10. Regarding the magnitude of the refractive index n of the first capping layer 201, reference may be made to the subsequent introduction, and description is not expanded here.

It can be understood that the intermolecular minimum center-of-mass distance Rm1(min) of the first capping layer material, the dimension c1 of the molecular structure of the first capping layer material in the third direction Z, and the molecular volume Vm1 and the molecular density ρm1 of the first capping layer material depend on the structure of the first capping layer material. Regarding the structure of the first capping layer material, reference may be made to the subsequent introduction, and description is not expanded here.

In some embodiments, a difference in refractive index n between two adjacent capping layers 20 is in a range of 0.2 to 0.8, inclusive.

It will be noted that the two adjacent capping layers 20 here refer to any two adjacent capping layers 20.

For example, the difference in refractive index n between two adjacent capping layers 20 is 0.2, 0.3, 0.4, 0.5, 0.6, 0.7 or 0.8, which is not limited here.

For example, as shown in FIG. 1, a difference between the refractive index n1 of the first capping layer 201 and the refractive index n2 of the second capping layer 202 is in a range of 0.2 to 0.8, inclusive. That is to say, the refractive index n1 of the first capping layer 201 is 0.2 to 0.8 greater than the refractive index n2 of the second capping layer 202. A difference between the refractive index n(m−1) of the (m−1)th capping layer and the refractive index nm of the mth capping layer is in a range of 0.2 to 0.8, inclusive, where m is a positive integer greater than or equal to 3. That is to say, the refractive index n(m−1) of the (m−1)th capping layer is 0.2 to 0.8 greater than the refractive index nm of the mth capping layer.

The light extraction efficiency of the light-emitting device 10 may be improved by setting the difference in refractive index n between two adjacent capping layers 20 to be in the range of 0.2 to 0.8, inclusive.

In some embodiments, as shown in FIGS. 1 and 4, the at least two capping layers 20 further include a second capping layer 202, and the second capping layer 202 is disposed on a side of the first capping layer 201 away from the second electrode 13.

The second capping layer 202 includes a second capping layer material, and an intermolecular minimum center-of-mass distance Rm2(min) of the second capping layer material and a dimension c2 of the molecular structure of the second capping layer material in the third direction Z satisfy at least one of the following conditions: the intermolecular minimum center-of-mass distance Rm2(min) of the second capping layer material is in a range of 2.5 Å to 10 Å, inclusive (i.e., 2.5 Å≤Rm2(min)≤10 Å), and the dimension c2 of the molecular structure of the second capping layer material in the third direction Z is in a range of 6 Å to 25 Å, inclusive (i.e., 6 Å≤c2≤25 Å).

For example, the intermolecular minimum center-of-mass distance Rm2(min) of the second capping layer material is 2.5 Å, 4 Å, 5.5 Å, 8 Å or 10 Å, which is not limited here.

For example, the dimension c2 of the molecular structure of the second capping layer material in the third direction Z is 6 Å, 10 Å, 13 Å, 15 Å, 18 Å, 20 Å, 23 Å or 25 Å, which is not limited here.

A molecular volume Vm2 and a molecular density ρm2 of the second capping layer material satisfy at least one of the following conditions: the molecular volume Vm2 of the second capping layer material is in a range of 6000 Bohr³ to 20000 Bohr³, inclusive (i.e., 6000 Bohr³≤Vm2≤20000 Bohr³), and the molecular density ρm2 of the second capping layer material is in a range of 0.8 g/cm³ to 1.48 g/cm³, inclusive (i.e. 0.8 g/cm³≤ρm2≤1.48 g/cm³).

For example, the molecular volume Vm2 of the second capping layer material is 6000 Bohr³, 8000 Bohr³, 10000 Bohr³, 13000 Bohr³ or 20000 Bohr³, which is not limited here.

For example, the molecular density ρm2 of the second capping layer material is 0.8 g/cm³, 1.0 g/cm³, 1.1 g/cm³, 1.2 g/cm³, 1.3 g/cm³, 1.4 g/cm³ or 1.48 g/cm³, which is not limited here.

The intermolecular minimum center-of-mass distance Rm1(min) of the first capping layer material and the dimension c1 of the molecular structure of the first capping layer material in the third direction Z satisfy at least one of the following conditions, that is, the intermolecular minimum center-of-mass distance Rm1(min) of the first capping layer material is in the range of 2 Å to 6 Å, inclusive (i.e., 2 Å≤Rm1(min)≤6 Å), and the dimension c1 of the molecular structure of the first capping layer material in the third direction Z is in the range of 3 Å to 15 Å, inclusive (i.e., 3 Å≤c1≤15 Å). The intermolecular minimum center-of-mass distance Rm2(min) of the second capping layer material and the dimension c2 of the molecular structure of the second capping layer material in the third direction Z satisfy at least one of the following conditions: the intermolecular minimum center-of-mass distance Rm2(min) of the second capping layer material is in the range of 2.5 Å to 10 Å, inclusive (i.e., 2.5 Å≤Rm2(min)≤10 Å), and the dimension c2 of the molecular structure of the second capping layer material in the third direction Z is in the range of 6 Å to 25 Å, inclusive (i.e., 6 Å≤c2≤25 Å).

Moreover, the molecular volume Vm1 and the molecular density ρm1 of the first capping layer material satisfy at least one of the following conditions, that is, the molecular volume Vm1 of the first capping layer material is in the range of 4000 Bohr³ to 8000 Bohr³, inclusive (i.e., 4000 Bohr³≤Vm1≤8000 Bohr³), and the molecular density ρm1 of the first capping layer material is in the range of 1.2 g/cm³ to 2.6 g/cm³, inclusive (i.e. 1.2 g/cm³≤ρm1≤2.6 g/cm³). The molecular volume Vm2 and the molecular density ρm2 of the second capping layer material satisfy at least one of the following conditions: the molecular volume Vm2 of the second capping layer material is in the range of 6000 Bohr³ to 20000 Bohr³, inclusive (i.e., 6000 Bohr³≤Vm2≤20000 Bohr³), and the molecular density ρm2 of the second capping layer material is in the range of 0.8 g/cm³ to 1.48 g/cm³, inclusive (i.e. 0.8 g/cm³≤ρm2≤1.48 g/cm³).

That is, it is set as that 2 Å≤Rm1(min)≤6 Å and/or 3 Å≤c1≤15 Å, 2.5 Å≤Rm2(min)≤10 Å and/or 6 Å≤c2≤25 Å, 4000 Bohr³≤Vm1≤8000 Bohr³ and/or 1.2 g/cm³≤ρm1≤2.6 g/cm³, 6000 Bohr³≤Vm2≤20000 Bohr³ and/or 0.8 g/cm³≤ρm2≤1.48 g/cm³. In addition, it can be seen from the above that the refractive index n of the material is negatively correlated with the intermolecular minimum center-of-mass distance Rm(min), negatively correlated with the dimension c of the molecular structure in the third direction Z, negatively correlated with the molecular volume Vm, and positively correlated with the molecular density ρm. In this way, the refractive index n1 of the first capping layer 201 of the light-emitting device 10 is caused to be greater than the refractive index n2 of the second capping layer 202 of the light-emitting device 10, and thus the light extraction efficiency of the light-emitting device 10 may be improved.

In some embodiments, as shown in FIG. 4, the at least two capping layers 20 include a first capping layer 201 and a second capping layer 202, and the first capping layer 201 is closer to the second electrode 13 than the second capping layer 202.

Within the light-emitting wavelength range of 300 nm to 800 nm, the refractive index n1 of the first capping layer 201 is in a range of 1.85 to 3.0, inclusive (i.e., 1.85≤n1≤3.0), and the refractive index n2 of the second capping layer 202 is in a range of 1.0 to 1.75, inclusive (i.e., 1.0≤n2≤1.75).

For example, within the light-emitting wavelength range of 300 nm to 800 nm, that is, within the visible light range, the refractive index n1 of the first capping layer 201 is 1.85, 2.0, 2.3, 2.5 or 3.0, which is not limited here.

For example, within the wavelength range of 300 nm to 800 nm, the refractive index n2 of the second capping layer 202 is 1.0, 1.2, 1.4, 1.6 or 1.75, which is not limited here.

By setting the refractive index n1 of the first capping layer 201 to be in the range of 1.85 to 3.0, inclusive, and the refractive index n2 of the second capping layer 202 to be in the range of 1.0 to 1.75, inclusive, the refractive index n1 of the first capping layer 201 is greater than the refractive index n2 of the second capping layer 202. Therefore, the optical waveguide effect may be reduced, thereby improving the light extraction efficiency of the light-emitting device 10.

In some embodiments, the first capping layer material is selected from any one of structures shown in the following general formula I.

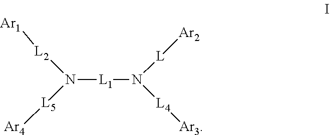

Where L₁ is selected from any of substituted or unsubstituted arylene, substituted or unsubstituted fused ring arylene, substituted or unsubstituted heteroarylene, and substituted or unsubstituted fused ring heteroarylene.

L₂, L₃, L₄ and L₅ are the same or different, and are each independently selected from any of substituted or unsubstituted C2 to C30 alkylene, substituted or unsubstituted C6 to C60 arylene, and substituted or unsubstituted C5 to C60 heteroarylene.

Ar₁, Ar₂, Ar₃ and Ar₄ are the same or different, and are each independently selected from any of substituted or unsubstituted C2 to C30 alkyl, substituted or unsubstituted C6 to C60 aryl, and substituted or unsubstituted C5 to C60 heteroaryl.

It will be noted that alkyl, aryl and heteroaryl of Cn refer to a corresponding group with n carbon (C) atoms. The aryl may be phenyl, and the heteroaryl may be furyl, pyranyl, thienyl or pyridyl.

For example, L₁ is selected from any of the structural formulas

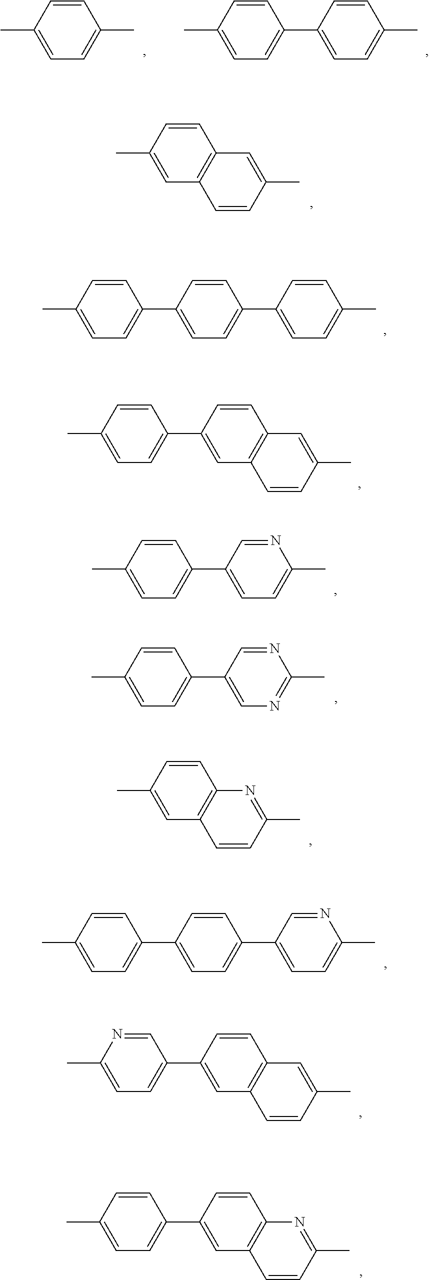

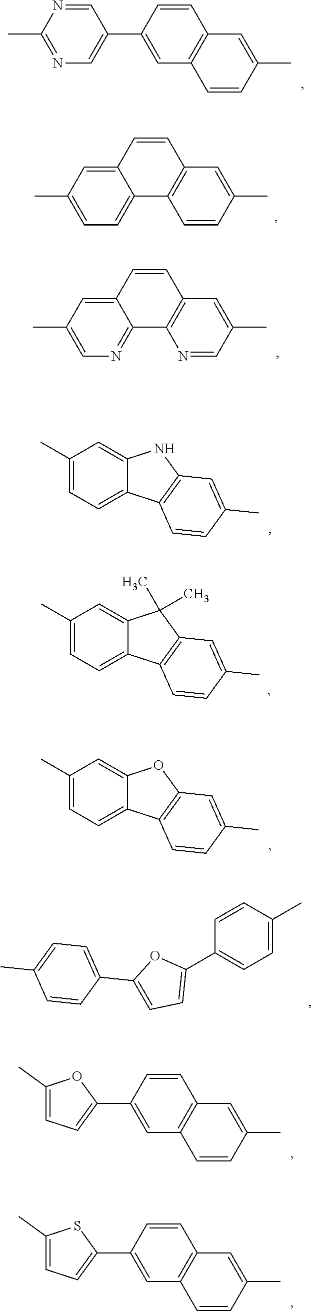

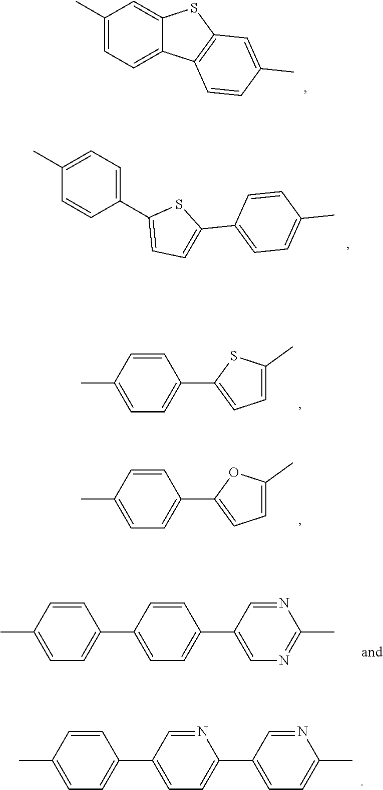

For example, Ar₁, Ar₂, Ar₃ and Ar₄ are each independently selected from any of substituted or unsubstituted phenyl, substituted or unsubstituted naphthyl, substituted or unsubstituted anthryl, substituted or unsubstituted pyrimidinyl and substituted or unsubstituted dibenzo five-membered heterocycle.

For example, Ar₁, Ar₂, Ar₃ and Ar₄ are each independently selected from any of the structural formulas

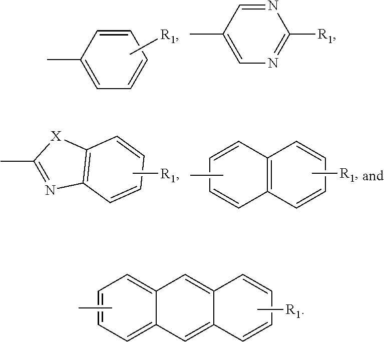

Where R₁ is selected from any of hydrogen, substituted or unsubstituted C2 to C30 alkyl, substituted or unsubstituted C6 to C60 aryl, and substituted or unsubstituted C5 to C60 heteroaryl. X is selected from any of carbon, nitrogen, oxygen and sulfur.

For example, the structural formula of the first capping layer material may be shown in the following formula.

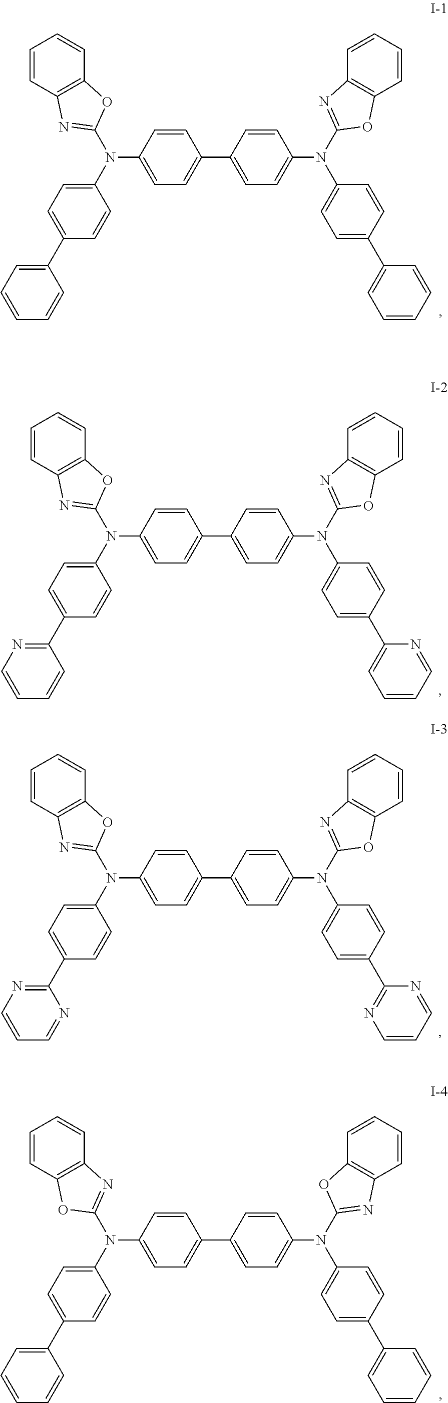 [SMILES: c1ccc(-c2ccc(N(c3ccc(-c4ccc(N(c5ccc(-c6ccccc6)cc5)c5nc6ccccc6o5)cc4)cc3)c3nc4ccccc4o3)cc2)cc1 ; c1ccc(-c2ccc(N(c3ccc(-c4ccc(N(c5ccc(-c6ccccn6)cc5)c5nc6ccccc6o5)cc4)cc3)c3nc4ccccc4o3)cc2)nc1 ; c1cnc(-c2ccc(N(c3ccc(-c4ccc(N(c5ccc(-c6ncccn6)cc5)c5nc6ccccc6o5)cc4)cc3)c3nc4ccccc4o3)cc2)nc1 ; c1ccc(-c2ccc(N(c3ccc(-c4ccc(N(c5ccc(-c6ccccc6)cc5)c5nc6ccccc6o5)cc4)cc3)c3nc4ccccc4o3)cc2)cc1]

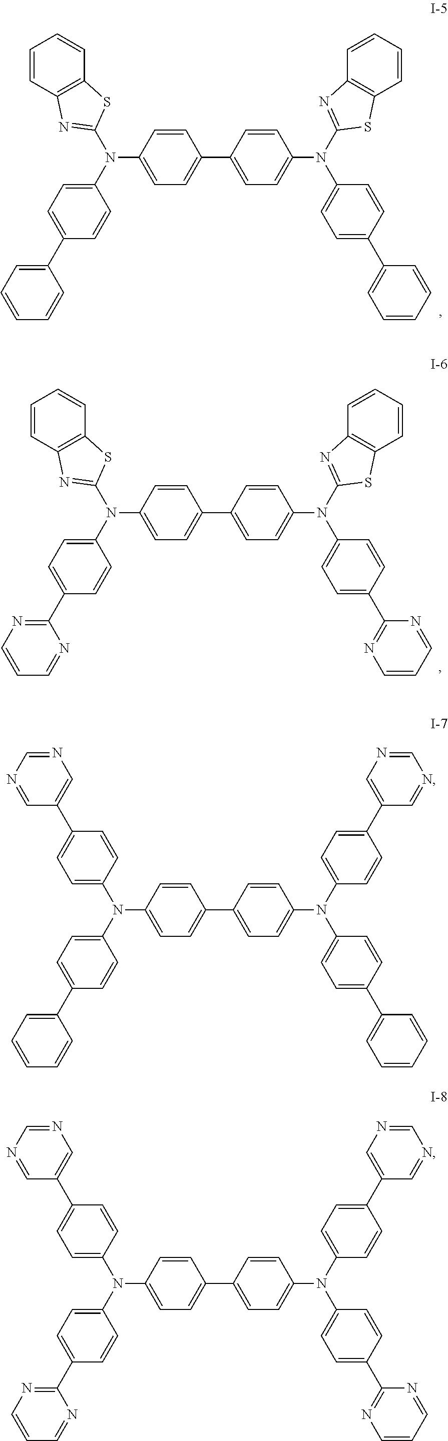 [SMILES: c1ccc(-c2ccc(N(c3ccc(-c4ccc(N(c5ccc(-c6ccccc6)cc5)c5nc6ccccc6s5)cc4)cc3)c3nc4ccccc4s3)cc2)cc1 ; c1cnc(-c2ccc(N(c3ccc(-c4ccc(N(c5ccc(-c6ncccn6)cc5)c5nc6ccccc6s5)cc4)cc3)c3nc4ccccc4s3)cc2)nc1 ; c1ccc(-c2ccc(N(c3ccc(-c4ccc(N(c5ccc(-c6ccccc6)cc5)c5ccc(-c6cncnc6)cc5)cc4)cc3)c3ccc(-c4cncnc4)cc3)cc2)cc1 ; c1cnc(-c2ccc(N(c3ccc(-c4ccc(N(c5ccc(-c6cncnc6)cc5)c5ccc(-c6ncccn6)cc5)cc4)cc3)c3ccc(-c4cncnc4)cc3)cc2)nc1]

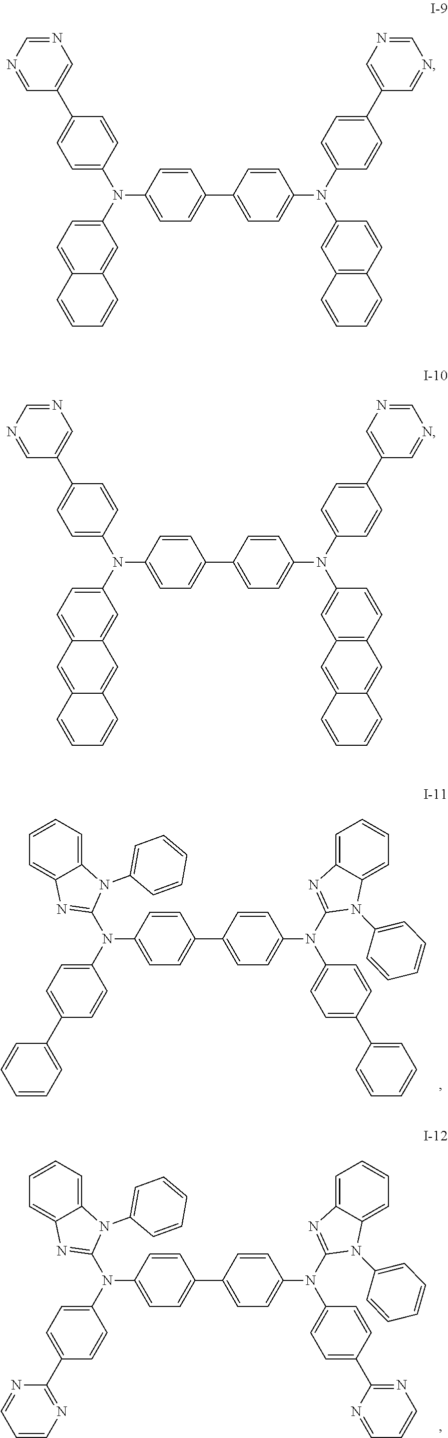 [SMILES: c1ccc2cc(N(c3ccc(-c4ccc(N(c5ccc(-c6cncnc6)cc5)c5ccc6ccccc6c5)cc4)cc3)c3ccc(-c4cncnc4)cc3)ccc2c1 ; c1ccc2cc3cc(N(c4ccc(-c5ccc(N(c6ccc(-c7cncnc7)cc6)c6ccc7cc8ccccc8cc7c6)cc5)cc4)c4ccc(-c5cncnc5)cc4)ccc3cc2c1 ; c1ccc(-c2ccc(N(c3ccc(-c4ccc(N(c5ccc(-c6ccccc6)cc5)c5nc6ccccc6n5-c5ccccc5)cc4)cc3)c3nc4ccccc4n3-c3ccccc3)cc2)cc1 ; c1ccc(-n2c(N(c3ccc(-c4ccc(N(c5ccc(-c6ncccn6)cc5)c5nc6ccccc6n5-c5ccccc5)cc4)cc3)c3ccc(-c4ncccn4)cc3)nc3ccccc32)cc1]

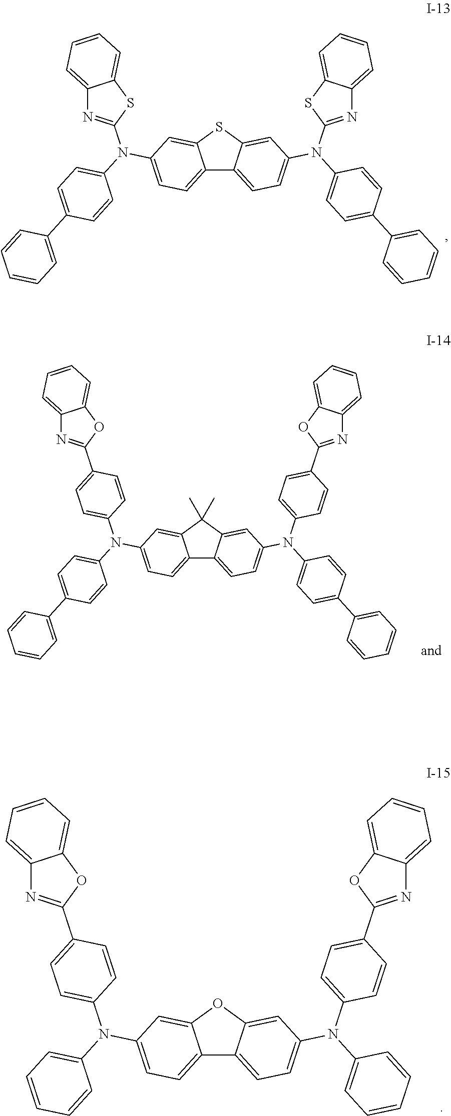 [SMILES: c1ccc(-c2ccc(N(c3ccc4c(c3)sc3cc(N(c5ccc(-c6ccccc6)cc5)c5nc6ccccc6s5)ccc34)c3nc4ccccc4s3)cc2)cc1 ; CC1(C)c2cc(N(c3ccc(-c4ccccc4)cc3)c3ccc(-c4nc5ccccc5o4)cc3)ccc2-c2ccc(N(c3ccc(-c4ccccc4)cc3)c3ccc(-c4nc5ccccc5o4)cc3)cc21 ; c1ccc(N(c2ccc(-c3nc4ccccc4o3)cc2)c2ccc3c(c2)oc2cc(N(c4ccccc4)c4ccc(-c5nc6ccccc6o5)cc4)ccc23)cc1]

It will be noted that I-x in the above structural formulas is a name of each structural formula and is not part of the structure with the structural formula, where x takes a positive integer, and the same goes for the following.

The structural formulas listed above are examples of the structure of the first capping layer material, and are not limitations on the structure of the first capping layer material.

The first capping layer material provided by the embodiments of the present disclosure has a core structure of bis-aromatic amine. For molecules with such type of structure, the dimension c of the molecular structure in the third direction Z is relatively small, the molecular volume Vm is relatively small, and the molecular density ρm is relatively large. This is beneficial to increase the refractive index n of the material, so that the first capping layer material has a relatively high refractive index n1. Within the light-emitting wavelength range of 300 nm to 800 nm, the refractive index n1 of the first capping layer 201 is in the range of 1.85 to 3.0, inclusive.

For example, for the first capping layer material shown as the structural formulas I-7, I-8 and I-15, this type of first capping layer material contains a triphenylamine group. In a case where the first capping layer material has a high refractive index n1, the first capping layer material also has a certain torsion property. In this way, the stability of the first capping layer 201 may increase and the life of the light-emitting device 10 may be improved. For the first capping layer material shown as the structural formulas I-1, I-2, I-3, I-4, I-5, I-6, I-11, I-12, I-13, I-14 and I-15, this type of first capping layer material contains a benzo five-membered heterocyclic substituent, the five-membered heterocyclic ring is connected to benzene to have a planar structure, which may increase conjugative property and increase the refractive index n1 of the first capping layer material.

Moreover, the first capping layer material has strong absorption at a wavelength of 400 nm. Therefore, the first capping layer material may absorb part of ultraviolet light, thereby prolonging the service life of the light-emitting device 10.

In some embodiments, the second capping layer material is selected from any of structures shown in the following general formula II.

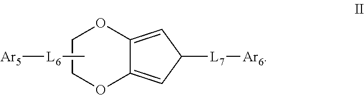

Where Ar₅ and Ar₆ are the same or different, and are each independently selected from any of

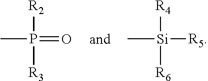

R₂, R₃, R₄, R₅ and R₆ are the same or different, and are each independently selected from any of substituted or unsubstituted C2 to C30 alkyl, substituted or unsubstituted C6 to C60 aryl, and substituted or unsubstituted C5 to C60 heteroaryl.

L₆ and L₇ are the same or different, and are each independently selected from any of a single bond, substituted or unsubstituted C2 to C30 alkylene, substituted or unsubstituted C6 to C60 arylene, and substituted or unsubstituted C5 to C60 heteroarylene.

For example, the structural formula of the second capping layer material may be shown in the following formula.

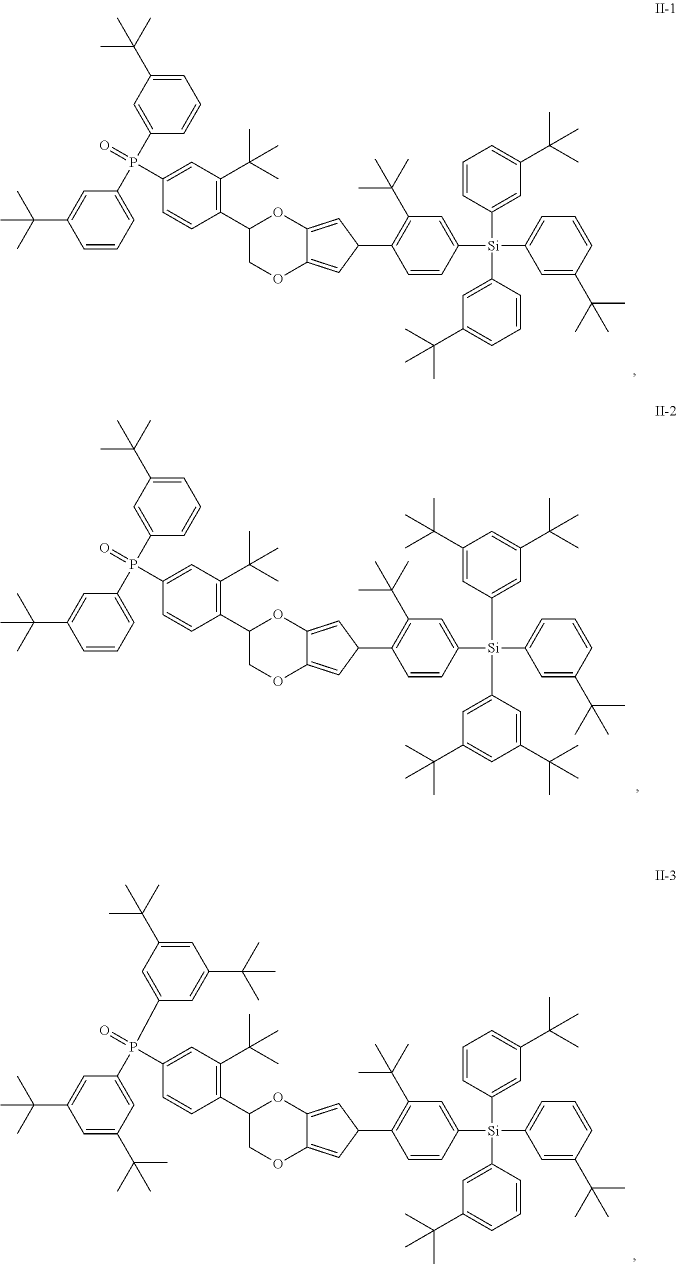

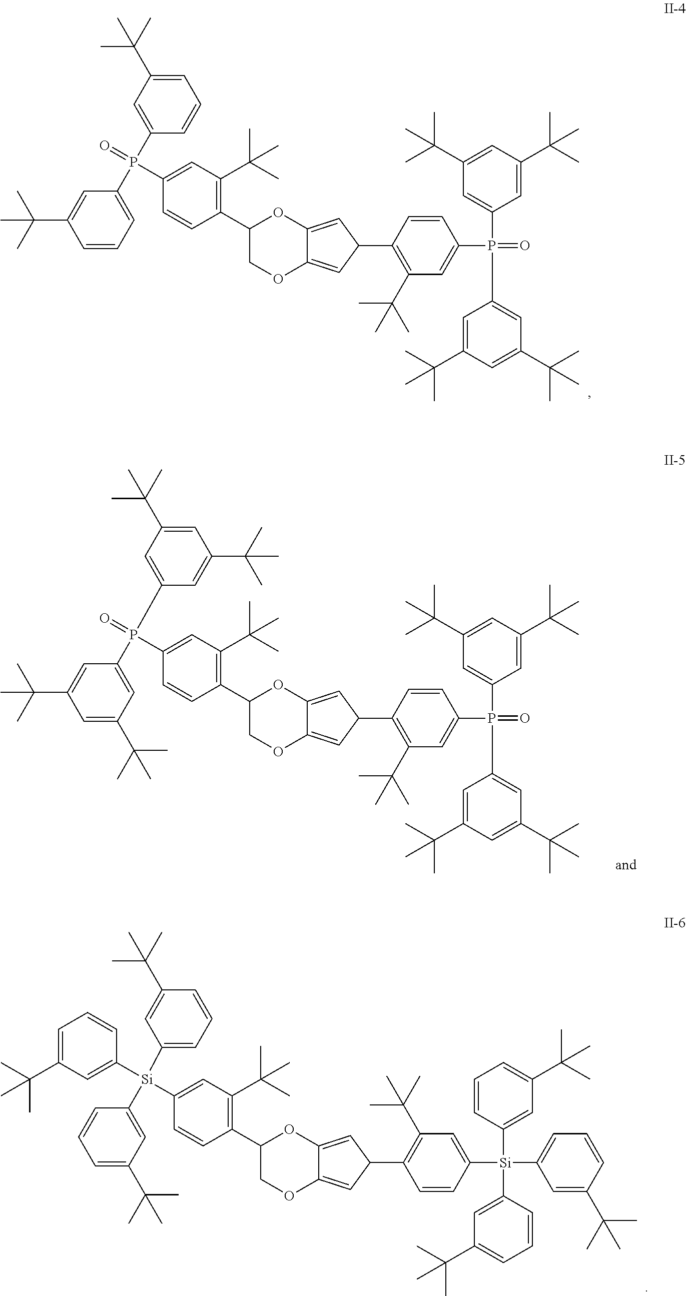

The second capping layer material has a core structure of dioxy-substituted cyclohexane five-membered ring, and contains a phosphorus-oxy group and a substituent of tetra-substituted silicon (Si). The oxygen-substituted cyclohexane, the phosphorus-oxy group and the tetra-substituted silicon (Si) may decrease conjugative property of the structure, thereby reducing the refractive index n2 of the second capping layer material. For example, the second capping layer material shown as the structural formula II-1 to the structural formula II-6 contains a plurality of tert-butyl substituents, which may increase the volume of the structure of the second capping layer material, thereby reducing the refractive index n2 of the second capping layer material.

Therefore, the molecular structure of the second capping layer material provided by the embodiments of the present disclosure has a relatively large height, a relatively large molecular volume Vm, and a relatively small molecular density ρm. This is beneficial to reducing the refractive index n of the material, so that in the formed light-emitting device 10, the refractive index n1 of the first capping layer 201 is greater than the refractive index n2 of the second capping layer 202, thereby improving the light extraction efficiency of the light-emitting device 10.

Based on the first capping layer materials and the second capping layer materials provided in the above examples, physical property parameters of some of the materials are shown in Table 1 below.

TABLE 1

| | Minimum | | | | | | |
|---|---|---|---|---|---|---|---|
| | center-of-mass | Molecular | Molecular | Molecular | Refractive | Refractive | Refractive |
| | distance | height c | volume | density | index n | index n | index n |
| Compound | Rm(min) (Å) | (Å) | Vm (Bohr³) | ρm (g/cm³) | (450 nm) | (550 nm) | (650 nm) |
| CPL-1 | 6.05 | 16.12 | 9241.08 | 1.29 | 1.90 | 1.83 | 1.79 |
| Alq3 | 6.15 | 8.2 | 3455.70 | 1.49 | 1.79 | 1.74 | 1.70 |
| I-1 | 3.14 | 8.97 | 5850.52 | 1.39 | 2.17 | 2.06 | 1.99 |
| I-3 | 3.13 | 8.92 | 5843.68 | 1.39 | 2.19 | 2.10 | 2.05 |
| I-4 | 3.36 | 9.26 | 6563.27 | 1.49 | 2.31 | 2.15 | 2.06 |
| I-14 | 3.41 | 9.46 | 6629.64 | 1.55 | 2.16 | 2.03 | 1.94 |
| II-1 | 2.72 | 14.95 | 11059.22 | 1.14 | 1.61 | 1.58 | 1.56 |
| II-3 | 2.89 | 15.49 | 11474.32 | 1.21 | 1.60 | 1.57 | 1.55 |
| II-4 | 2.69 | 13.88 | 9116.43 | 1.39 | 1.58 | 1.55 | 1.53 |
| II-5 | 2.86 | 14.45 | 9469.58 | 1.46 | 1.57 | 1.54 | 1.52 |

In the related art, the material of the capping layer includes CPL-1 and/or tris-(8-hydroxyquinoline)aluminum (Alq3), and the structural formulas of CPL-1 and Alq3 are as follows.

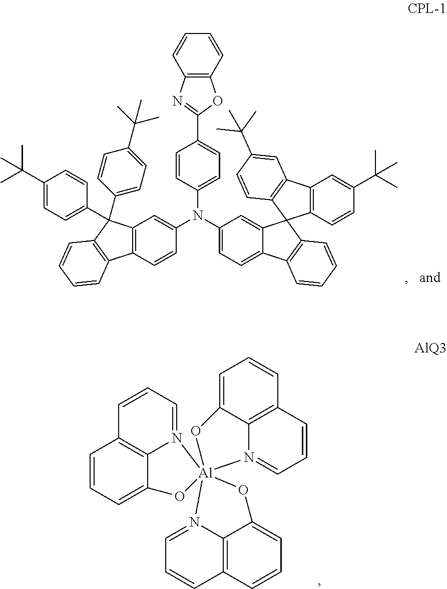

The physical property parameters of different materials can be seen in Table 1. The physical property parameters include the intermolecular minimum center-of-mass distance Rm, the dimension c of the molecular structure in the third direction Z, the molecular volume Vm and the molecular density ρm, which affect the refractive index n of the material on lights with different wavelengths of light.

Therefore, adjusting the appropriate range of physical property parameters of the materials of the capping layers 20 to facilitate reduction of the optical waveguide effect and improvement of the light extraction efficiency of the light-emitting device 10.

In some embodiments, as shown in FIG. 4, a thickness d1 of the first capping layer 201 is in a range of 50 nm to 90 nm, inclusive; and a thickness d2 of the second capping layer 202 is in a range of 50 nm to 90 nm, inclusive.

For example, as shown in FIG. 4, the light-emitting device 10 includes a first electrode 11, a light-emitting layer 12, a second electrode 13, a first capping layer 201 and a second capping layer 202 that are stacked in sequence in a fourth direction T. The thickness d1 of the first capping layer 201 is a dimension of the first capping layer 201 in the fourth direction T, and the thickness d2 of the second capping layer 202 is a dimension of the second capping layer 202 in the fourth direction T.

For example, the thickness d1 of the first capping layer 201 is 50 nm, 60 nm, 70 nm, 80 nm or 90 nm, and is not limited here.

For example, the thickness d2 of the second capping layer 202 is 50 nm, 60 nm, 70 nm, 80 nm or 90 nm, and is not limited here.

It will be noted that the thickness d1 of the first capping layer 201 and the thickness d2 of the second capping layer 202 may be set according to the wavelength of the light emitted by the light-emitting layer 12 in combination with the microcavity effect of the light-emitting device 10, so as to improve the light extraction efficiency of the light-emitting device 10.

In some embodiments, as shown in FIG. 1, the light-emitting device 10 is a top-emission device, and the at least two capping layers 20 are disposed on a light-exiting side of the light-emitting device 10.

For example, as shown in FIG. 4, the light-emitting device 10 includes a first electrode 11, a light-emitting layer 12, a second electrode 13, a first capping layer 201 and a second capping layer 202 that are stacked in sequence in the fourth direction T. The fourth direction T is parallel to the light extraction direction E of the light-emitting device 10. The first capping layer 201 and the second capping layer 202 are provided on the light-exiting side of the light-emitting device 10.

The first capping layer 201 and the second capping layer 202 are provided to improve the light extraction efficiency of the light-emitting device 10.

In some examples, as shown in FIGS. 1 and 4, the first electrode 11 is an anode, and the second electrode 13 is a cathode.

For example, the material of the anode includes indium tin oxide (ITO), and the material of the cathode includes a magnesium-silver alloy. For example, in the magnesium-silver alloy, the mass proportion of magnesium is 10%.

For example, as shown in FIG. 4, the light-emitting device 10 is a top-emission upright light-emitting device. The light-emitting device 10 includes a first electrode 11, a light-emitting layer 12 and a second electrode 13 that are stacked in sequence in the fourth direction T, and the second electrode 13 (cathode) is located on the light-exiting side. That is, the light-emitting device 10 is an upright light-emitting device.

The cathode material of the upright light-emitting device is a magnesium-silver alloy, which may achieve a light transmittance of 55%. The square resistance of the cathode is about 12Ω. The setting of the cathode material may make the light-emitting device 10 have a relatively good light extraction efficiency.

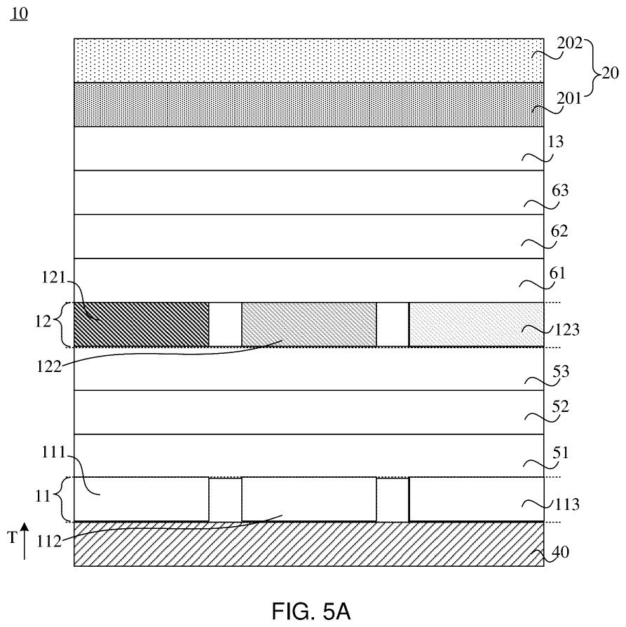

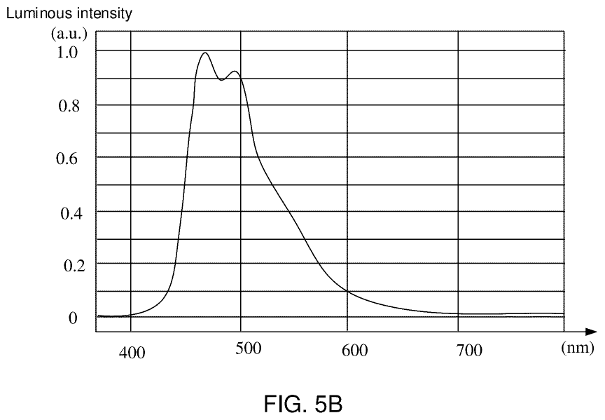

In some embodiments, as shown in FIG. 5A, the light-emitting layer 12 includes: a first sub-pixel light-emitting layer 121, a second sub-pixel light-emitting layer 122 and a third sub-pixel light-emitting layer 123. The first sub-pixel light-emitting layer 121 is configured to emit one of red light, blue light and green light, the second sub-pixel light-emitting layer 122 is configured to emit another of red light, blue light and green light, and the third sub-pixel light-emitting layer 123 is configured to emit the last one of red light, blue light and green light.

For example, the first sub-pixel light-emitting layer 121 is configured to emit blue light, the second sub-pixel light-emitting layer 122 is configured to emit green light, and the third sub-pixel light-emitting layer 123 is configured to d emit red light.

In some examples, as shown in FIG. 5A, any of the first sub-pixel light-emitting layer 121, the second sub-pixel light-emitting layer 122 and the third sub-pixel light-emitting layer 123 is configured to emit blue light. The material of the sub-pixel light-emitting layer that emits blue light includes a host material and a guest material.

For example, the first sub-pixel light-emitting layer 121 is configured to emit blue light. The material of the first sub-pixel light-emitting layer 121 includes a host material and a guest material.

For example, the host material includes AND, where the structural formula of AND is as follows:

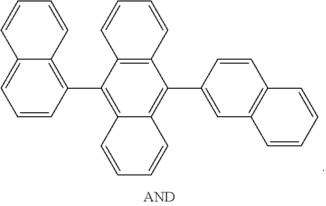 [SMILES: c1ccc2cc(-c3c4ccccc4c(-c4cccc5ccccc45)c4ccccc34)ccc2c1]

For example, the guest material includes DSA-Ph, where the structural formula of DSA-Ph is as follows:

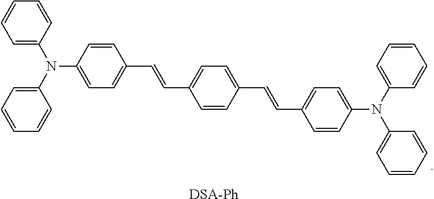 [SMILES: C(=C\c1ccc(N(c2ccccc2)c2ccccc2)cc1)/c1ccc(/C=C/c2ccc(N(c3ccccc3)c3ccccc3)cc2)cc1 ; "DSA-Ph"]

For example, the mass proportion of the guest material to the material of the first sub-pixel light-emitting layer 121 is 3%.

The material of the first sub-pixel light-emitting layer 121 is provided to include the host material and the guest material. The host material can perform energy transfer with the guest material, and has good and matching transport capabilities of holes and electrons, thereby improving the luminous efficiency of the light-emitting device 10.

For example, as shown in FIG. 5B, the material of the first sub-pixel light-emitting layer 121 includes the host material and the guest material. In a case where the guest material includes DSA-Ph, FIG. 5B shows an electroluminescence spectrum map of the luminescent material. In the figure, a horizontal axis represents wavelength, and a vertical axis represents luminous intensity. It can be seen from the figure that the guest material DSA-Ph has a relatively strong luminous intensity in the wavelength range of 450 nm to 550 nm.

For example, as shown in FIG. 5A, the first electrode 11, the light-emitting layer 12, the second electrode 13, the first capping layer 201 and the second capping layer 202 are stacked in sequence on a side of the base substrate 40 in the fourth direction T. The first electrode 11 includes a first sub-electrode 111, a second sub-electrode 112 and a third sub-electrode 113. The first sub-electrode 111 is provided in correspondence to the first sub-pixel light-emitting layer 121, the second sub-electrode 112 is provided in correspondence to the second sub-pixel light-emitting layer 122, and the third sub-electrode 113 is provided in correspondence to the third sub-pixel light-emitting layer 123.

It will be noted that the above “correspondence” between A and B means that in the fourth direction T, orthographic projections of A and B on the base substrate 40 are overlapped.

In addition, the description of “stacked in sequence” in the embodiments of the present disclosure does not mean sequential contact, and other film layer(s) may also be provided therein.

For example, the base substrate 40 may be an array substrate, and the array substrate includes a thin film transistor array. For example, the array substrate includes a substrate, and an active layer, a gate insulating layer, a gate metal layer, an interlayer insulating layer, a source and drain metal layer and a planarization layer that are stacked in sequence on the substrate. The first electrode 11 is disposed on a side of the planarization layer away from the substrate. In some other examples, the base substrate 40 may be a substrate, and other film layer(s), such as an active layer, a gate insulating layer, a gate metal layer, an interlayer insulating layer, a source and drain metal layer and a planarization layer, are provided between the substrate and the first electrode 11.

In some embodiments, as shown in FIGS. 1, 4 and 5A, the material of the light-emitting layer 12 includes any of a fluorescent luminescent material, a phosphorescent luminescent material and a thermally activated delayed fluorescent material.

It will be noted that the fluorescent luminescent material is made by calcining metal (such as zinc, chromium) sulfides or rare earth oxides in combination with trace activators, is colorless or light white, and exhibits various colors of visible light (400 nm to 800 nm) under irradiation of under ultraviolet light (200 nm to 400 nm) depending on types and contents of metal and activator in the material. Singlet excitons and triplet excitons generated after the phosphorescent luminescent material is excited may both emit light when transitioning to the ground state, so that the internal quantum efficiency (IQE) of the light-emitting device 10 based on phosphorescent luminescence reaches 100%. The thermally activated delayed fluorescent (TADF) material is a material with a relatively small energy level difference (ΔEST) between singlet excitons and triplet excitons.

The material of the light-emitting layer 12 may adopt any of the fluorescent luminescent material, the phosphorescent luminescent material and the thermally activated delayed fluorescent material. The combination of the material of the light-emitting layer 12 and at least one capping layer 20 provided by the embodiments of the present disclosure may improve the light extraction efficiency of the light-emitting device 10.

In some embodiments, as shown in FIG. 5A, the light-emitting device 10 further includes at least one of a hole injection layer 51, a hole transport layer 52 and an electron blocking layer 53 that is provided between the first electrode 11 and the light-emitting layer 12. The light-emitting device 10 further includes at least one of a hole blocking layer 61, an electron transport layer 62 and an electron injection layer 63 that is provided between the light-emitting layer 12 and the second electrode 13.

At least one of the hole injection layer 51, the hole transport layer 52 and the electron blocking layer 53 is provided between the first electrode 11 and the light-emitting layer 12, and at least one of the hole blocking layer 61, the electron transport layer 62 and the electron injection layer 63 is provided between the light-emitting layer 12 and the second electrode 13. Thus, the efficiency of injecting electrons and holes into the light-emitting layer 12 may be improved.

For example, as shown in FIG. 5A, the light-emitting device 10 includes a first electrode 11, a hole injection layer 51, a hole transport layer 52, an electron blocking layer 53, a light-emitting layer 12, a hole blocking layer 61, an electron transport layer 62, an electron injection layer 63, a second electrode 13, a first capping layer 201 and a second capping layer 202 which are stacked in sequence in the fourth direction T.

For example, the material of the hole injection layer 51 includes 2,3,6,7,10,11-hexacyano-1,4,5,8,9,12-hexaazatriphenylenehexacabonitrile, which is represented as HAT-CN. The structural formula of HAT-CN is as follows.

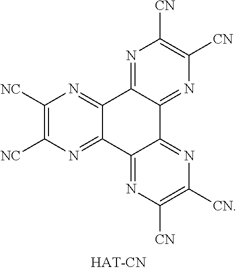 [SMILES: N#Cc1nc2c3nc(C#N)c(C#N)nc3c3nc(C#N)c(C#N)nc3c2nc1C#N]

For example, the material of the hole transport layer 52 includes N,N′-Bis-(1-naphthalenyl)-N,N′-bis-phenyl-(1,1′-biphenyl)-4,4′-diamine, which is represented as NPB. The structural formula of NPB is as follows.

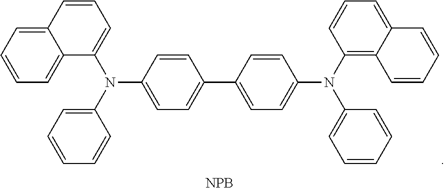 [SMILES: c1ccc(N(c2ccc(-c3ccc(N(c4ccccc4)c4cccc5ccccc45)cc3)cc2)c2cccc3ccccc23)cc1 ; "NPB"]

For example, the material of the electron blocking layer 53 includes 4,4′,4″-tris(carbazol-9-yl)triphenylamine, which is represented as TCTA. The structural formula of TCTA is as follows.

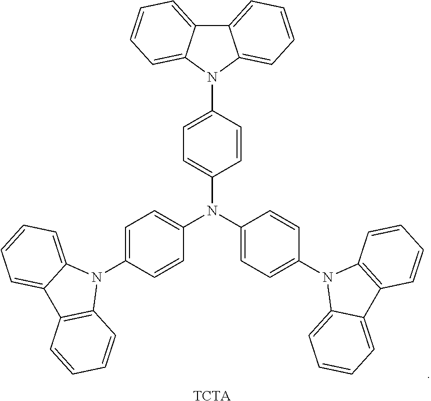 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; "TCTA"]

For example, the material of the hole blocking layer 61 includes 1,3,5-tris(1-phenyl-1H-benzimidazol-2-yl)benzene, which is represented as TPBi. The structural formula of TPBi is as follows.

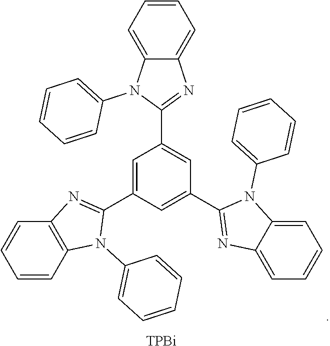

For example, the material of the electron transport layer 62 includes nitrogen-containing heterocyclic compound BPhen, and 8-hydroxyquinolinolato-lithium (LiQ₃) doped in BPhen. The structural formulas of BPhen and LiQ₃ are as follows.

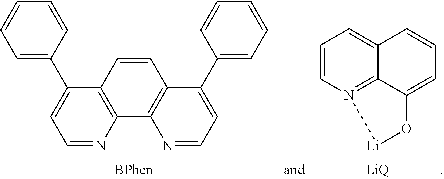

For example, the material of the electron injection layer 63 may be ytterbium (Yb).

In order to objectively evaluate technical effects of the embodiments of the present disclosure, technical solutions provided by embodiments of the present disclosure will be exemplarily described for detail below through the following embodiments and comparative examples.

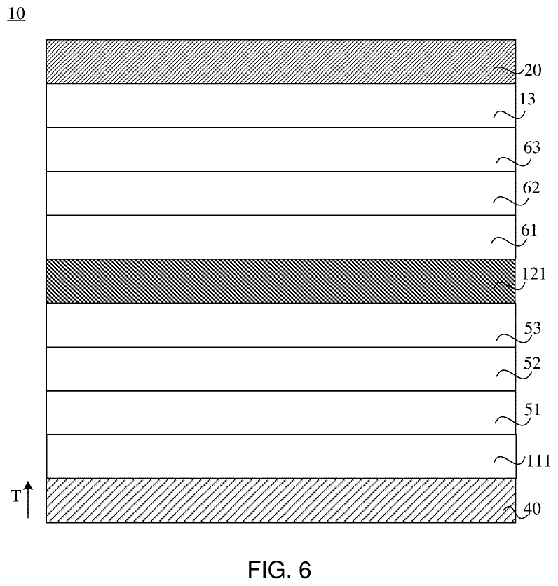

In the following embodiments and comparative examples, as shown in FIG. 6, a base substrate 40 provided with an ITO layer (e.g., a first sub-electrode 111) is first cleaned and dried, and a hole injection layer 51, a hole transport layer 52, an electron blocking layer 53, a first sub-pixel light-emitting layer 121, a hole blocking layer 61, an electron transport layer 62, an electron injection layer 63 and a second electrode 13 are sequentially formed on the first sub-electrode 111.

The above structure is expressed as hole injection layer 51 (10 nm)/hole transport layer 52 (110 nm)/electron blocking layer 53 (5 nm)/first sub-pixel light-emitting layer 121, BH:BD (20 nm, 3%)/hole blocking layer 61 (5 nm)/electron transport layer 62: LiQ₃ (30 nm, 50%)/electron injection layer 63 (1 nm)/second electrode 13, Mg:Ag (13 nm).

It will be noted that the 10 nm in the hole injection layer 51 (10 nm) means that a dimension of the hole injection layer 51 in the fourth direction T is 10 nm, that is, the thickness of the hole injection layer 51 is 10 nm. The rest are the same, and are not described again here.

In BH:BD (20 nm, 3%), BH:BD means that the material of the first sub-pixel light-emitting layer 121 includes a host material BH and a guest material BD, and 3% means that the mass proportion of the guest material to the material of the first sub-pixel light-emitting layer 121 is 3%. In the electron transport layer 62: LiQ₃ (30 nm, 50%), 50% means that the mass proportion of LiQ₃ to the material of the electron transport layer 62 is 50%. Mg:Ag means that the material of the second electrode 13 includes a magnesium-silver alloy. For example, in the magnesium-silver alloy, the mass proportion of magnesium is 10%.

For example, the material of the hole injection layer 51 includes HAT-CN, the material of the hole transport layer 52 includes NPB, the material of the electron blocking layer 53 includes TCTA, the host material BH includes AND, the guest material BD includes DSA-Ph, the material of the hole blocking layer 61 includes TPBi, the material of the electron transport layer 62 includes BPhen and LiQ₃, and the material of the electron injection layer 63 includes Yb. Regarding the structural formulas of HAT-CN, NPB, TCTA, AND, DSA-Ph, TPBi, LiQ₃ and BPhen, reference may be made to the above content and details are not repeated here.

In the following embodiments and comparative examples, as shown in FIG. 6, the light-emitting device 10 includes different capping layer(s) 20.

In Comparative Example 1, the capping layer(s) 20 of the light-emitting device 10 include a single layer. For example, a dimension of the capping layer 20 in the fourth direction T is 65 nm. The material of the capping layer 20 includes CPL-1. Regarding the structural formula of CPL-1, reference may be made to the above content and details are not repeated here.

In Comparative Example 2, the capping layer(s) 20 of the light-emitting device 10 include a single layer. For example, a dimension of the capping layer 20 in the fourth direction T is 65 nm. The material of the capping layer 20 includes Alq3. Regarding the structural formula of Alq3, reference may be made to the above content and details are not repeated here.

In Comparative Example 3, the capping layer(s) 20 of the light-emitting device 10 include two layers. The material of the first layer includes CPL-1 and the material of the second layer includes Alq3. The first layer is closer to the second electrode 13 than the second layer. A dimension of the first layer in the fourth direction T is 65 nm, and a dimension of the second layer in the fourth direction T is 65 nm.

In Embodiment 1, the light-emitting device 10 includes a first capping layer 201 and a second capping layer 202 (as shown in FIG. 4). The structural formula of the first capping layer material is shown as I-1, and the structural formula of the second capping layer material is shown as II-1.

In Embodiment 2, the light-emitting device 10 includes a first capping layer 201 and a second capping layer 202. The structural formula of the first capping layer material is shown as I-3, and the structural formula of the second capping layer material is shown as II-3.

In Embodiment 3, the light-emitting device 10 includes a first capping layer 201 and a second capping layer 202. The structural formula of the first capping layer material is shown as I-4, and the structural formula of the second capping layer material is shown as II-4.

In Embodiment 4, the light-emitting device 10 includes a first capping layer 201 and a second capping layer 202. The structural formula of the first capping layer material is shown as I-14, and the structural formula of the second capping layer material is shown as II-5.

In Embodiment 5, the light-emitting device 10 includes a first capping layer 201 and a second capping layer 202. The structural formula of the first capping layer material is shown as I-3, and the structural formula of the second capping layer material is shown as II-4.

In Embodiment 6, the light-emitting device 10 includes a first capping layer 201 and a second capping layer 202. The structural formula of the first capping layer material is shown as I-3, and the structural formula of the second capping layer material is shown as II-5.

In Embodiment 7, the light-emitting device 10 includes a first capping layer 201 and a second capping layer 202. The structural formula of the first capping layer material is shown as I-4, and the structural formula of the second capping layer material is shown as II-5.

In Embodiment 8, the light-emitting device 10 includes a first capping layer 201 and a second capping layer 202. The structural formula of the first capping layer material is shown as I-1, and the structural formula of the second capping layer material is shown as II-5.

The physical property parameters of materials with structural formulas shown as I-1, I-3, I-4, I-14, II-1, II-3, II-4 and II-5 are shown in Table 1, and are not repeated here.

Regarding the specific structures of materials with structural formulas shown as I-1, I-3, I-4, I-14, II-1, II-3, II-4 and II-5, reference may be made to the above content and details are not repeated here.

In Embodiments 1 to 8, a dimension of the first capping layer 201 in the fourth direction T is 65 nm, and a dimension of the second capping layer 202 in the fourth direction T is 65 nm.

Based on the above comparative examples and embodiments, the luminous efficiency and life of the light-emitting device 10 are tested. In Comparative Example 1 to Comparative Example 3 and Embodiment 1 to Embodiment 8, test conditions of the light-emitting devices 10 are all the same, and the luminous efficiency and life of each light-emitting device 10 are shown in Table 2.

TABLE 2

| Light-emitting | First capping | Second capping | Luminous | |
|---|---|---|---|---|
| device | layer material | layer material | efficiency | Life |
| Comparative | CPL-1 | — | 100% | 100% |
| Example 1 | | | | |
| Comparative | — | Alq3 | 98% | 99% |
| Example 2 | | | | |
| Comparative | CPL-1 | Alq3 | 105% | 104% |
| Example 3 | | | | |
| Embodiment 1 | I-1 | II-1 | 120% | 116% |
| Embodiment 2 | I-3 | II-3 | 122% | 119% |
| Embodiment 3 | I-4 | II-4 | 125% | 118% |
| Embodiment 4 | I-14 | II-5 | 118% | 115% |
| Embodiment 5 | I-3 | II-4 | 126% | 123% |
| Embodiment 6 | I-3 | II-5 | 124% | 117% |
| Embodiment 7 | I-4 | II-5 | 128% | 119% |
| Embodiment 8 | I-1 | II-5 | 116% | 114% |

It can be seen from Table 2 that, the light-emitting device 10 provided by the embodiments of the present disclosure includes a first capping layer 201 and a second capping layer 202, and the luminous efficiency and life of the light-emitting device 10 obtained by using the first capping layer material and the second capping layer material provided by the embodiments of the present disclosure are significantly better than those of the comparative examples. Therefore, the light-emitting device 10 provided by the embodiments of the present disclosure improves the light extraction efficiency of the light-emitting device 10.

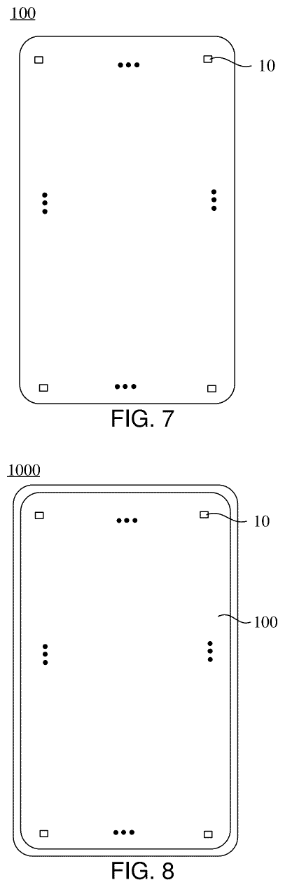

As shown in FIG. 7, some embodiments of the present disclosure provide a light-emitting substrate 100, and the light-emitting substrate 100 includes the light-emitting device 10 as described in any of the above embodiments.

For example, the light-emitting substrate 100 further includes a driving circuit connected to each light-emitting device 10. The driving circuit may be connected to a control circuit to drive each light-emitting device 10 to emit light according to an electrical signal input by the control circuit. The driving circuit may be an active driving circuit or a passive driving circuit.

In some examples, the light-emitting substrate 100 may emit white light, monochromatic light (light of a single color), or color-adjustable light. In this example, the light-emitting substrate 100 may be used for illumination (i.e., it may be used in an illumination apparatus), or may be used to display images or pictures (i.e., it may be used in a display apparatus).

The beneficial effects of the light-emitting substrate 100 are the same as the beneficial effects of the light-emitting device 10 provided in the foregoing embodiments of the present disclosure, and details are not described here again.

As shown in FIG. 8, some embodiments of the present disclosure provide a light-emitting apparatus 1000. The light-emitting apparatus 1000 includes the light-emitting substrate 100 provided in the above embodiments. Of course, the light-emitting apparatus 1000 may also include other components. For example, the light-emitting apparatus 1000 may include a circuit used for providing electrical signals for the light-emitting substrate 100 to drive the light-emitting substrate 100 to emit light, and the circuit may be called a control circuit and may include a circuit board and/or an integrated circuit (IC) electrically connected to the light-emitting substrate 100.

In some embodiments, the light-emitting apparatus 1000 may be an illumination apparatus. In this case, the light-emitting apparatus 1000 is used as a light source to implement an illumination function. For example, the light-emitting apparatus 1000 may be a backlight module in a liquid crystal display apparatus, a lamp for internal or external illumination, or various signal lamps.

In some other embodiments, the light-emitting apparatus 1000 may be a display apparatus. In this case, the light-emitting substrate is a display substrate for realizing the function of displaying images (i.e., pictures). The light-emitting apparatus 1000 may include a display or a product including the display. The display may be a flat panel display (FPD), a micro display, and the like. According to whether a user can see a scene behind the display, the display may be a transparent display or an opaque display. According to whether the display can be bent or curled, the display may be a flexible display or a common display (which may be referred to as a rigid display). For example, the product including the display may include a computer display, a television, a billboard, a laser printer with a display function, a telephone, a mobile phone, a personal digital assistant (PDA), a laptop computer, a digital camera, a portable camcorder, a viewfinder, a vehicle, a large-area wall, a screen in a theater or a sign in a stadium.

The beneficial effects of the light-emitting apparatus 1000 are the same as the beneficial effects of the light-emitting device 10 provided in the foregoing embodiments of the present disclosure, and details are not described here again.

The foregoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

1. A light-emitting device, comprising a first electrode and a second electrode, and a light-emitting layer disposed between the first electrode and the second electrode; and
the light-emitting device further comprising at least two capping layers stacked on a side of the second electrode away from the first electrode; a material of each capping layer in the at least two capping layers including an organic material; and a refractive index of a capping layer relatively closer to the second electrode being greater than a refractive index of a capping layer relatively farther away from the second electrode; wherein
the at least two capping layers include a first capping layer, and the first capping layer is closest to the second electrode; the first capping layer includes a first capping layer material, and an intermolecular minimum center-of-mass distance of the first capping layer material and a dimension of a molecular structure of the first capping layer material in a third direction satisfy at least one of the following conditions: the intermolecular minimum center-of-mass distance of the first capping layer material is in a range of 2 Å to 6 Å, inclusive, and the dimension of the molecular structure of the first capping layer material in the third direction is in a range of 3 Å to 15 Å, inclusive; and
a molecular volume and a molecular density of the first capping layer material satisfy at least one of the following conditions: the molecular volume of the first capping layer material is in a range of 4000 Bohr³ to 8000 Bohr³, inclusive, and the molecular density of the first capping layer material is in a range of 1.2 g/cm³ to 2.6 g/cm³, inclusive; wherein
the molecular structure has a dimension in a first direction, a dimension in a second direction and the dimension in the third direction, the first direction, the second direction and the third direction are perpendicular to each other; and the dimension in the first direction is greater than or equal to the dimension in the second direction, and the dimension in the second direction is greater than or equal to the dimension in the third direction.

2. The light-emitting device according to claim 1, wherein a difference in refractive index between two adjacent capping layers is in a range of 0.2 to 0.8, inclusive.

3. The light-emitting device according to claim 1, wherein the at least two capping layers further include a second capping layer, and the second capping layer is disposed on a side of the first capping layer away from the second electrode;
the second capping layer includes a second capping layer material, and an intermolecular minimum center-of-mass distance of the second capping layer material and a dimension of a molecular structure of the second capping layer material in the third direction satisfy at least one of the following conditions: the intermolecular minimum center-of-mass distance of the second capping layer material is in a range of 2.5 Å to 10 Å, inclusive, and the dimension of the molecular structure of the second capping layer material in the third direction is in a range of 6 Å to 25 Å, inclusive; and
a molecular volume and a molecular density of the second capping layer material satisfy at least one of the following conditions: the molecular volume of the second capping layer material is in a range of 6000 Bohr³ to 20000 Bohr³, inclusive, and the molecular density of the second capping layer material is in a range of 0.8 g/cm³ to 1.48 g/cm³, inclusive.

4. The light-emitting device according to claim 1, wherein the at least two capping further layers a second capping layer; and
within a light-emitting wavelength range of 300 nm to 800 nm, a refractive index of the first capping layer is in a range of 1.85 to 3.0, inclusive, and a refractive index of the second capping layer is in a range of 1.0 to 1.75, inclusive.

5. The light-emitting device according to claim 1, wherein the first capping layer material is selected from any one of structures represented by a following general formula I: 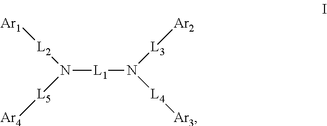
wherein L₁ is selected from any one of substituted or unsubstituted arylene, substituted or unsubstituted fused ring arylene, substituted or unsubstituted heteroarylene, and substituted or unsubstituted fused ring heteroarylene;
L₂, L₃, L₄ and L₅ are the same or different, and are each independently selected from any one of substituted or unsubstituted C2 to C30 alkylene, substituted or unsubstituted C6 to C60 arylene, and substituted or unsubstituted C5 to C60 heteroarylene; and
Ar₁, Ar₂, Ar₃ and Ar₄ are the same or different, and are each independently selected from any one of substituted or unsubstituted C2 to C30 alkyl, substituted or unsubstituted C6 to C60 aryl, and substituted or unsubstituted C5 to C60 heteroaryl.

6. The light-emitting device according to claim 5, wherein L₁ is selected from any one of structural formulas

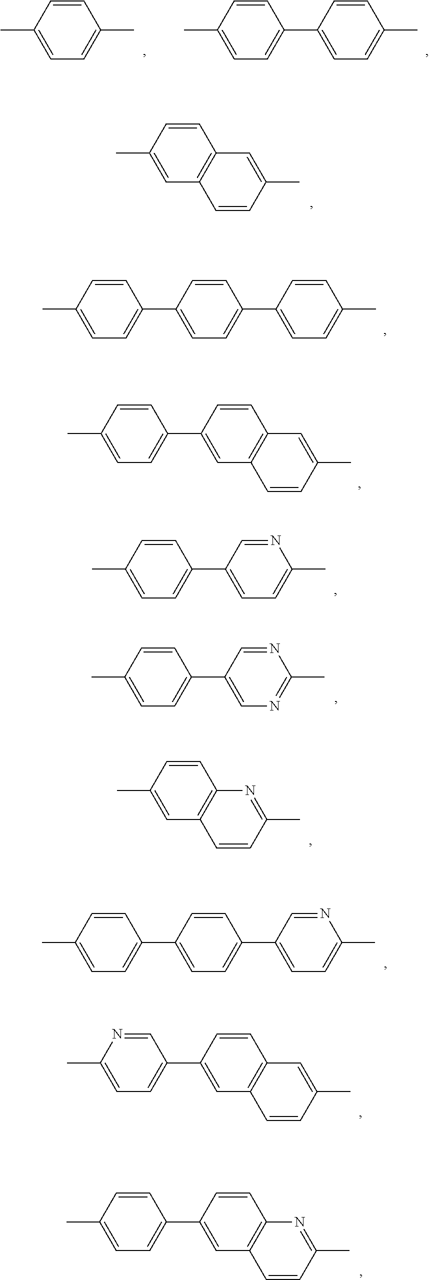

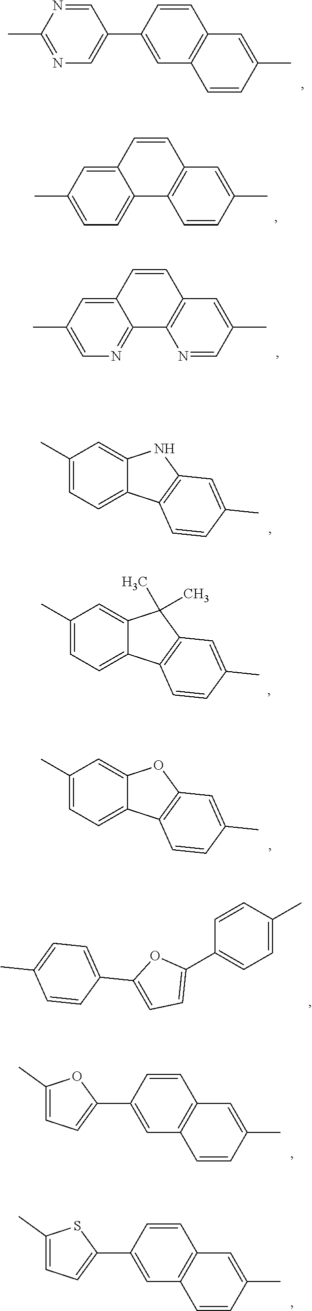

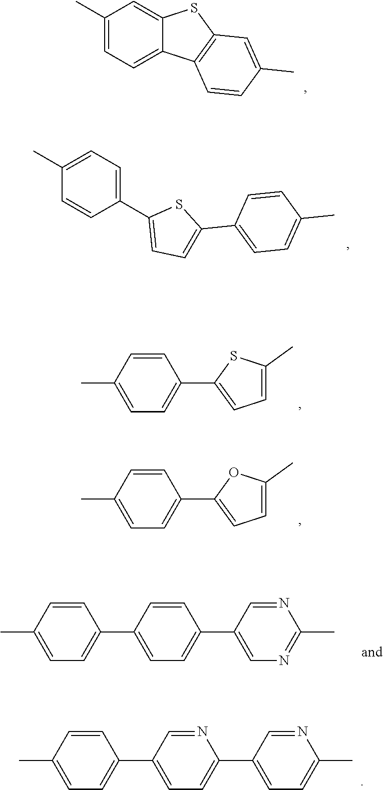

7. The light-emitting device according to claim 5, wherein Ar₁, Ar₂, Ar₃ and Ar₄ are each independently selected from any one of substituted or unsubstituted phenyl, substituted or unsubstituted naphthyl, substituted or unsubstituted anthryl, substituted or unsubstituted pyrimidinyl and substituted or unsubstituted dibenzo five-membered heterocycle.

8. The light-emitting device according to claim 5, wherein Ar₁, Ar₂, Ar₃ and Ar₄ are each independently selected from any one of structural formulas 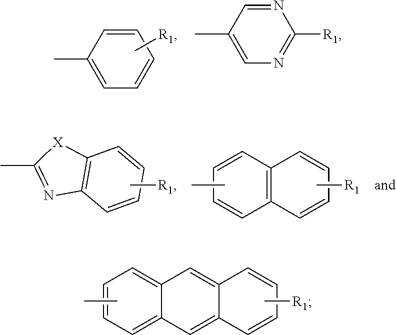
wherein R₁ is selected from any one of hydrogen, substituted or unsubstituted C2 to C30 alkyl, substituted or unsubstituted C6 to C60 aryl, and substituted or unsubstituted C5 to C60 heteroaryl, and X is selected from any one of carbon, nitrogen, oxygen and sulfur.

9. The light-emitting device according to claim 3, wherein the second capping layer material is selected from any one of structures represented by a following general formula II: 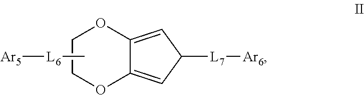
wherein Ar₅ and Ar₆ are the same or different, and are each independently selected from any one of 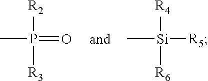
R₂, R₃, R₄, R₅ and R₆ are the same or different, and are each independently selected from any one of substituted or unsubstituted C2 to C30 alkyl, substituted or unsubstituted C6 to C60 aryl, and substituted or unsubstituted C5 to C60 heteroaryl; and
L₆ and L₇ are the same or different, and are each independently selected from any one of a single bond, substituted or unsubstituted C2 to C30 alkylene, substituted or unsubstituted C6 to C60 arylene, and substituted or unsubstituted C5 to C60 heteroarylene.

10. The light-emitting device according to claim 3, wherein
a thickness of the first capping layer is in a range of 50 nm to 90 nm, inclusive; and
a thickness of the second capping layer is in a range of 50 nm to 90 nm, inclusive.

11. The light-emitting device according to claim 1, wherein the light-emitting device is a top-emission device, and the at least two capping layers are disposed on a light-exiting side of the light-emitting device.

12. The light-emitting device according to claim 11, wherein the first electrode is an anode, and the second electrode is a cathode.

13. The light-emitting device according to claim 1, wherein the light-emitting layer includes a first sub-pixel light-emitting layer, a second sub-pixel light-emitting layer and a third sub-pixel light-emitting layer, wherein
the first sub-pixel light-emitting layer is configured to emit one of red light, blue light and green light, the second sub-pixel light-emitting layer is configured to emit another of the red light, the blue light and the green light, and the third sub-pixel light-emitting layer is configured to emit a last one of the red light, the blue light and the green light.

14. The light-emitting device according to claim 13, wherein a material of the light-emitting layer includes any one of a fluorescent luminescent material, a phosphorescent luminescent material and a thermally activated delayed fluorescent material.

15. The light-emitting device according to claim 13, wherein any one of the first sub-pixel light-emitting layer, the second sub-pixel light-emitting layer and the third sub-pixel light-emitting layer is configured to emit the blue light; and
a material of a sub-pixel light-emitting layer that emits the blue light includes a host material and a guest material, wherein
a structural formula of the host material is as follows: 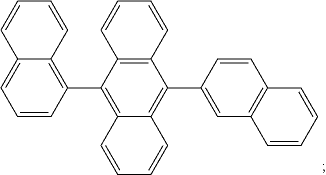 [SMILES: c1ccc2cc(-c3c4ccccc4c(-c4cccc5ccccc45)c4ccccc34)ccc2c1]
and
a structural formula of the guest material is as follows:

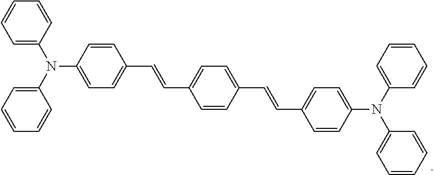 [SMILES: C(=C\c1ccc(N(c2ccccc2)c2ccccc2)cc1)/c1ccc(/C=C/c2ccc(N(c3ccccc3)c3ccccc3)cc2)cc1]

16. The light-emitting device according to claim 1, further comprising:
at least one of a hole injection layer, a hole transport layer and an electron blocking layer that is disposed between the first electrode and the light-emitting layer; and
at least one of a hole blocking layer, an electron transport layer and an electron injection layer that is disposed between the light-emitting layer and the second electrode.

17. A light-emitting substrate, comprising the light-emitting device according to claim 1.

18. A light-emitting apparatus, comprising the light-emitting substrate according to claim 17.
